(19) United States
(12) Patent Application Publication
(10) Pub. No.: US 2008/0293198 A1
(43) Pub. Date: Nov. 27, 2008

(54) Method for manufacturing semiconductor device including etching process of silicon nitride film

(75) Inventors: Tatsuki Kojima, Kanagawa (JP); Kenji Tsujita, Kumamoto (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/078,288

(22) Filed: Mar. 28, 2008

(30) Foreign Application Priority Data
Mar. 30, 2007 (JP) 91126/2007

(51) Int. Cl. H01L 21/336; H01L 21/28

(52) U.S. Cl. 438/259; 438/700; 257/E21.158; 257/E21.422

(57) ABSTRACT

A manufacturing method of a semiconductor device includes the step for forming a silicon nitride film having a first part where arsenic is included and a second part where less amount of or substantially no arsenic is included, the step for removing at least a portion of the first part by dry etching, and the step for removing at least a portion of the second part by wet etching. Since arsenic in the silicon nitride film is removed by dry etching, arsenic is never eluted into the wet etching liquid from the silicon nitride film during subsequent wet etching. Therefore, one can prevent the wet etching from being contaminated. Etching of the silicon nitride film is performed by a combination of dry etching and wet etching. Therefore, compared with the case where etching is performed only by dry etching, plasma damage to the region exposed in the plasma atmosphere except for the silicon nitride film can be decreased.

### BACKGROUND OF THE INVENTION

1. Field of the Invention

The present invention relates to a method for manufacturing a semiconductor device and, specifically, relates to a method for manufacturing a semiconductor device which includes a step for etching a silicon nitride film containing arsenic.

2. Description of Related Art

In a processing technology of a semiconductor device, an impurity diffusion technology for introducing impurities is used in order to have suitable conductivity and characteristics by mixing N-type and P-type impurities.

The impurity diffusion technology includes an ion implantation technique in which impurities such as boron (B), arsenic (As), and phosphorus (P) are ionized; high energy is imparted to the ionized impurities by an accelerating voltage to make them collide with the surface of the semiconductor. Moreover, selective implantation is performed when the impurities are injected only into a desired region. This selective implantation is performed by patterning, which has a hole opening, a resist being formed over the surface of the semiconductor and a stopper (mask) which is made of an oxide film or a nitride film and which blocks the ion implantation, and by injecting (implanting) impurity ions only into the desired region of the semiconductor surface.

Impurity diffusion technology is used in various parts for various purposes and under different conditions. For instance, there are steps for forming a well where deep implantation is achieved by high energy and steps for forming a source and a drain where shallow implantation is achieved by suppressing junction leakage with high concentration, etc. Moreover, in a step for manufacturing nonvolatile memory having a floating-gate, selective implantation of impurities into the channel region is performed in order to control the threshold voltage for reading data.

JP-A No. 1998-50636 discloses a method for manufacturing a Metal Oxide Semiconductor (MOS) transistor where the element region is masked by a nitride film and arsenic ions are introduced into the field oxide film (isolation region). FIG. 34 shows a part of the step for manufacturing a MOS transistor described in JP-A No. 1998-50636.

As shown in FIG. 34A, a silicon oxide film 72 and a silicon nitride film 73 are formed over a silicon substrate 71 in the element region; and a field oxide film 75 is formed over the silicon substrate 71 in the isolation region. Herein, selective implantation of arsenic ions is performed on the entire surface of the wafer with an implantation energy of 10 keV and a dosage of 3×10¹⁵ cm⁻². By using this ion implantation, arsenic is injected into the field oxide film 75 and the silicon nitride film 73 which is a mask. Arsenic injected into the field oxide film 73 works to effectively control the silicidation over the field oxide film 73.

Next, as shown in FIG. 34B, the silicon nitride film 73 which was used as a mask during the selective implantation of arsenic is removed by using a wet etching technique.

Next, as shown in FIG. 34C, by using a wet etching technique, the silicon oxide film 72 is removed and a gate oxide film 76 is formed by a thermal oxidation technique. Afterwards, by patterning the polysilicon, a polysilicon gate electrode 77 is formed over the gate oxide film 76. After forming the polysilicon gate electrode 77, a silicon nitride film is formed and a sidewall spacer 78 is formed by anisotropic dry etching.

In the following steps, after the source and drain of the transistor are formed, the upper part of the polysilicon gate electrode and the surface of the source and drain are silicided to form a MOS transistor.

Moreover, as shown in JP-A-2005-159336, removal of the silicon nitride film is generally performed by using a wet etching technique in which a chemical including phosphoric acid as a main component is used.

JP-A-1998-50636 describes a step of selective implantation of arsenic for preventing silicidation, and, in addition to this, a silicon nitride film is widely used for a mask during selective implantation of arsenic in a step of selective implantation of arsenic for forming the source and drain. When the role of a mask during selective implantation is over, the silicon nitride film which includes arsenic is removed by wet etching using phosphoric acid in the following treatment process. However, when the silicon nitride film is removed, arsenic included in the silicon nitride film is eluted into the wet etching liquid. At that time, the following reaction is observed in the wet etching liquid by arsenic (As) which is eluted and the silicon nitride film (Si, N) which is removed by wet etching.

Si₃N₄+As→SiₓN_{y}As_{z} (formula 1)

The reaction product (Si, N, As composition) created in the wet etching liquid are particles (fine particles), and particles act as dust in a manufacturing process of a semiconductor device. Particles acting as dust create wiring short circuits, pattern formation anomalies, and deterioration of the tolerance of the insulating film, etc. and cause a decrease in the yield of the semiconductor product and its reliability and deterioration in the performance. In other words, since there is a danger of developing a decrease in both productivity and quality of semiconductor devices, it becomes very important to remove particles created therein in a manufacturing process of a semiconductor device.

The present inventor has recognized that, in removal of such particles, it becomes necessary that there be not only an operation for cleaning where the contamination source is removed by cleaning the semiconductor device itself but also an exchange of the wet etching liquid where particles which become a source of contamination are mixed (contamination control). Specifically, since exchange of the wet etching liquid increases the production cost of the semiconductor device, it becomes a problem from the standpoint of the manufacturing cost if frequent exchange of the wet etching liquid is necessary.

### SUMMARY

The present invention seeks to solve one or more of the above problems, or to improve upon those problems at least in part.

In one embodiment, a method for manufacturing a semiconductor device includes forming a silicon nitride film having a first part where arsenic is included and a second part where less amount of or substantially no arsenic is included, removing at least a portion of the first part by dry etching, removing at least a portion of the second part by wet etching.

Specifically, arsenic in the silicon nitride film is removed by dry etching, so that arsenic is never eluted in the wet etching liquid from the silicon nitride film during the subsequent wet etching. Therefore, since no reaction products (particles) including arsenic are created in the wet etching liquid, contamination of the wet etching liquid can be suppressed. Moreover, etching of the silicon nitride is performed by combining the dry etching with the wet etching. Therefore, compared with the case of etching where only dry etching is performed, plasma damage can be decreased in the area exposed to the plasma atmosphere except for the silicon nitride film. As a result, it is possible to improve the productivity and the reliability of the semiconductor device.

In another embodiment, a method for manufacturing a semiconductor device includes forming a conductive layer for a floating gate over a semiconductor layer intervening a gate insulating film therebetween, removing the conductive layer selectively using a silicon nitride film having an opening as a mask, providing a first injection of arsenic using the silicon nitride film as a mask to form a first diffusion layer on the semiconductor layer located at a position corresponding to the opening, removing at least a part of a region where arsenic is included in the silicon nitride film by dry etching, and removing at least a part of a rest of the silicon nitride film by wet etching.

Thus, removal of the silicon nitride film used as a mask for arsenic implantation is carried out by combining dry etching and wet etching. As a result, it is possible to improve the productivity and the reliability of the semiconductor device.

In yet another embodiment, a method for manufacturing a semiconductor device includes covering a semiconductor substrate in an element region with a silicon nitride film, covering the semiconductor substrate in a different region from the element region with an isolation insulating film, injecting arsenic into the isolation insulating film using the silicon nitride film as a mask, removing at least a part of a region where arsenic is included in the silicon nitride film by dry etching, removing at least apart of a rest of the silicon nitride film by wet etching, forming a gate electrode over the semiconductor substrate intervening the gate insulating film therebetween in the element region, forming an impurity diffusion region which will be a source and drain on the semiconductor substrate in the element region, forming a metallic film over the entire surface; and performing a heat treatment to form a silicide layer by reacting the surface of the impurity diffusion region with the metallic film.

Thus, since the arsenic-containing region is removed by dry etching and the rest of the region is removed by wet etching, it is possible to improve the productivity and the reliability of the semiconductor device.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1A is a cross-sectional drawing illustrating a manufacturing process of a semiconductor device including an N-type diffusion region of the first embodiment in the present invention;

FIG. 1B is a cross-sectional drawing illustrating a manufacturing process of a semiconductor device including an N-type diffusion region of the first embodiment in the present invention;

FIG. 1C is a cross-sectional drawing illustrating a manufacturing process of a semiconductor device including an N-type diffusion region of the first embodiment in the present invention;

FIG. 2A is a cross-sectional drawing illustrating a manufacturing process of a semiconductor device including an N-type diffusion region of the first embodiment in the present invention;

FIG. 2B is a cross-sectional drawing illustrating a manufacturing process of a semiconductor device including an N-type diffusion region of the first embodiment in the present invention;

FIG. 2C is a cross-sectional drawing illustrating a manufacturing process of a semiconductor device including an N-type diffusion region of the first embodiment in the present invention;

FIG. 3A is a cross-sectional drawing illustrating a structure of a memory cell transistor of a split gate type nonvolatile memory of the second embodiment;

FIG. 3B is a plane-diagram (plane layout) illustrating a structure of a memory cell transistor of a split gate type nonvolatile memory of the second embodiment;

FIG. 4A is a conceptual drawing illustrating a write operation of a split gate type nonvolatile memory of the second embodiment;

FIG. 4B is a conceptual drawing illustrating an erase operation of a split gate type nonvolatile memory of the second embodiment;

FIG. 4C is a conceptual drawing illustrating a read operation of a split gate type nonvolatile memory of the second embodiment;

FIG. 5A is a cross-sectional drawing at A-A′ in FIG. 3B illustrating a manufacturing process of a split gate type nonvolatile memory of the second embodiment;

FIG. 5B is a cross-sectional drawing at B-B′ in FIG. 3B illustrating a manufacturing process of a split gate type nonvolatile memory of the second embodiment;

FIG. 6A is a cross-sectional drawing at A-A′ in FIG. 3B illustrating a manufacturing process of a split gate type nonvolatile memory of the second embodiment;

FIG. 6B is a cross-sectional drawing at B-B′ in FIG. 3B illustrating a manufacturing process of a split gate type nonvolatile memory of the second embodiment;

FIG. 7A is a cross-sectional drawing at A-A′ in FIG. 3B illustrating a manufacturing process of a split gate type nonvolatile memory of the second embodiment;

FIG. 7B is a cross-sectional drawing at B-B′ in FIG. 3B illustrating a manufacturing process of a split gate type nonvolatile memory of the second embodiment;

FIG. 8A is a cross-sectional drawing at A-A′ in FIG. 3B illustrating a manufacturing process of a split gate type nonvolatile memory of the second embodiment;

FIG. 8B is a cross-sectional drawing at B-B′ in FIG. 3B illustrating a manufacturing process of a split gate type nonvolatile memory of the second embodiment;

FIG. 9A is a cross-sectional drawing at A-A′ in FIG. 3B illustrating a manufacturing process of a split gate type nonvolatile memory of the second embodiment;

FIG. 9B is a cross-sectional drawing at B-B′ in FIG. 3B illustrating a manufacturing process of a split gate type nonvolatile memory of the second embodiment;

FIG. 10A is a cross-sectional drawing at A-A′ in FIG. 3B illustrating a manufacturing process of a split gate type nonvolatile memory of the second embodiment;

FIG. 10B is a cross-sectional drawing at B-B′ in FIG. 3B illustrating a manufacturing process of a split gate type nonvolatile memory of the second embodiment;

FIG. 11A is a cross-sectional drawing at A-A′ in FIG. 3B illustrating a manufacturing process of a split gate type nonvolatile memory of the second embodiment;

FIG. 11B is a cross-sectional drawing at B-B′ in FIG. 3B illustrating a manufacturing process of a split gate type nonvolatile memory of the second embodiment;

FIG. 12A is a cross-sectional drawing at A-A′ in FIG. 3B illustrating a manufacturing process of a split gate type nonvolatile memory of the second embodiment;

FIG. 12B is a cross-sectional drawing at B-B′ in FIG. 3B illustrating a manufacturing process of a split gate type nonvolatile memory of the second embodiment;

FIG. 13A is a cross-sectional drawing at A-A′ in FIG. 3B illustrating a manufacturing process of a split gate type nonvolatile memory of the second embodiment;

FIG. 13B is a cross-sectional drawing at B-B′ in FIG. 3B illustrating a manufacturing process of a split gate type nonvolatile memory of the second embodiment;

FIG. 14A is a cross-sectional drawing at A-A′ in FIG. 3B illustrating a manufacturing process of a split gate type nonvolatile memory of the second embodiment;

FIG. 14B is a cross-sectional drawing at B-B′ in FIG. 3B illustrating a manufacturing process of a split gate type nonvolatile memory of the second embodiment;

FIG. 15A is a cross-sectional drawing at A-A′ in FIG. 3B illustrating a manufacturing process of a split gate type nonvolatile memory of the second embodiment;

FIG. 15B is a cross-sectional drawing at B-B′ in FIG. 3B illustrating a manufacturing process of a split gate type nonvolatile memory of the second embodiment;

FIG. 16A is a cross-sectional drawing at A-A′ in FIG. 3B illustrating a manufacturing process of a split gate type nonvolatile memory of the second embodiment;

FIG. 16B is a cross-sectional drawing at B-B′ in FIG. 3B illustrating a manufacturing process of a split gate type nonvolatile memory of the second embodiment;

FIG. 17A is a cross-sectional drawing at A-A′ in FIG. 3B illustrating a manufacturing process of a split gate type nonvolatile memory of the second embodiment;

FIG. 17B is a cross-sectional drawing at B-B′ in FIG. 3B illustrating a manufacturing process of a split gate type nonvolatile memory of the second embodiment;

FIG. 18A is a cross-sectional drawing at A-A′ in FIG. 3B illustrating a manufacturing process of a split gate type nonvolatile memory of the second embodiment;

FIG. 18B is a cross-sectional drawing at B-B′ in FIG. 3B illustrating a manufacturing process of a split gate type nonvolatile memory of the second embodiment;

FIG. 19A is a cross-sectional drawing at A-A′ in FIG. 3B illustrating a manufacturing process of a split gate type nonvolatile memory of the second embodiment;

FIG. 19B is a cross-sectional drawing at B-B′ in FIG. 3B illustrating a manufacturing process of a split gate type nonvolatile memory of the second embodiment;

FIG. 20A is a cross-sectional drawing at A-A′ in FIG. 3B illustrating a manufacturing process of a split gate type nonvolatile memory of the second embodiment;

FIG. 20B is a cross-sectional drawing at B-B′ in FIG. 3B illustrating a manufacturing process of a split gate type nonvolatile memory of the second embodiment;

FIG. 21A is a cross-sectional drawing at A-A′ in FIG. 3B illustrating a manufacturing process of a split gate type nonvolatile memory of the second embodiment;

FIG. 21B is a cross-sectional drawing at B-B′ in FIG. 3B illustrating a manufacturing process of a split gate type nonvolatile memory of the second embodiment;

FIG. 22A is a cross-sectional drawing at A-A′ in FIG. 3B illustrating a manufacturing process of a split gate type nonvolatile memory of the second embodiment;

FIG. 22B is a cross-sectional drawing at B-B′ in FIG. 3B illustrating a manufacturing process of a split gate type nonvolatile memory of the second embodiment;

FIG. 23A is a cross-sectional drawing at A-A′ in FIG. 3B illustrating a manufacturing process of a split gate type nonvolatile memory of the second embodiment;

FIG. 23B is a cross-sectional drawing at B-B′ in FIG. 3B illustrating a manufacturing process of a split gate type nonvolatile memory of the second embodiment;

FIG. 24A is a cross-sectional drawing at A-A′ in FIG. 3B illustrating a manufacturing process of a split gate type nonvolatile memory of the second embodiment;

FIG. 24B is a cross-sectional drawing at B-B′ in FIG. 3B illustrating a manufacturing process of a split gate type nonvolatile memory of the second embodiment;

FIG. 25A is a cross-sectional drawing at A-A′ in FIG. 3B illustrating a manufacturing process of a split gate type nonvolatile memory of the second embodiment;

FIG. 25B is a cross-sectional drawing at B-B′ in FIG. 3B illustrating a manufacturing process of a split gate type nonvolatile memory of the second embodiment;

FIG. 26A is a cross-sectional drawing at A-A′ in FIG. 3B illustrating a manufacturing process of a split gate type nonvolatile memory of the second embodiment;

FIG. 26B is a cross-sectional drawing at B-B′ in FIG. 3B illustrating a manufacturing process of a split gate type nonvolatile memory of the second embodiment;

FIG. 27A is a cross-sectional drawing at A-A′ in FIG. 3B illustrating a manufacturing process of a split gate type nonvolatile memory of the second embodiment;

FIG. 27B is a cross-sectional drawing at B-B′ in FIG. 3B illustrating a manufacturing process of a split gate type nonvolatile memory of the second embodiment;

FIG. 28A is a cross-sectional drawing at A-A′ in FIG. 3B illustrating a manufacturing process of a split gate type nonvolatile memory of the second embodiment;

FIG. 28B is a cross-sectional drawing at B-B′ in FIG. 3B illustrating a manufacturing process of a split gate type nonvolatile memory of the second embodiment;

FIG. 29A is a cross-sectional drawing at A-A′ in FIG. 3B illustrating a manufacturing process of a split gate type nonvolatile memory of the second embodiment;

FIG. 29B is a cross-sectional drawing at B-B′ in FIG. 3B illustrating a manufacturing process of a split gate type nonvolatile memory of the second embodiment;

FIG. 30A is a cross-sectional drawing illustrating a manufacturing process of a MOS transistor having a silicide structure of the third embodiment;

FIG. 30B is a cross-sectional drawing illustrating a manufacturing process of a MOS transistor having a silicide structure of the third embodiment;

FIG. 30C is a cross-sectional drawing illustrating a manufacturing process of a MOS transistor having a silicide structure of the third embodiment;

FIG. 31A is a cross-sectional drawing illustrating a manufacturing process of a MOS transistor having a silicide structure of the third embodiment;

FIG. 31B is a cross-sectional drawing illustrating a manufacturing process of a MOS transistor having a silicide structure of the third embodiment;

FIG. 31C is a cross-sectional drawing illustrating a manufacturing process of a MOS transistor having a silicide structure of the third embodiment;

FIG. 32A is a cross-sectional drawing illustrating a manufacturing process of a MOS transistor having a silicide structure of the third embodiment;

FIG. 32B is a cross-sectional drawing illustrating a manufacturing process of a MOS transistor having a silicide structure of the third embodiment;

FIG. 32C is a cross-sectional drawing illustrating a manufacturing process of a MOS transistor having a silicide structure of the third embodiment;

FIG. 33A is a cross-sectional drawing illustrating a manufacturing process of a MOS transistor having a silicide structure of the third embodiment;

FIG. 33B is a cross-sectional drawing illustrating a manufacturing process of a MOS transistor having a silicide structure of the third embodiment;

FIG. 34A is a cross-sectional drawing illustrating a manufacturing process of a MOS transistor of the prior art;

FIG. 34B is a cross-sectional drawing illustrating a manufacturing process of a MOS transistor of the prior art; and

FIG. 34C is a cross-sectional drawing illustrating a manufacturing process of a MOS transistor of the prior art.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

The present invention relates to an etching technique of a silicon nitride film in a manufacturing process of a semiconductor device by combining a first etching process where a arsenic-containing region is removed by dry etching using a second etching process where the rest of the region is removed by wet etching when the silicon nitride film including arsenic in the upper part is removed. Then, in the first embodiment of the present invention, the concept of the present invention will be explained using a manufacturing process as an example where selective implantation is performed using the silicon nitride film as a mask and an N-type diffusion region is formed over a silicon substrate.

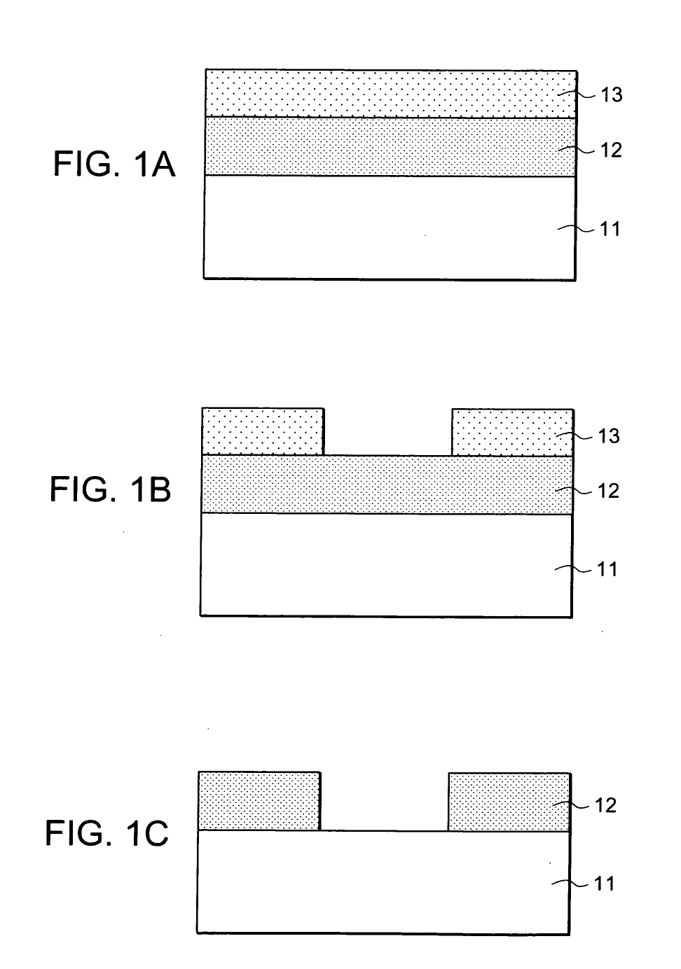

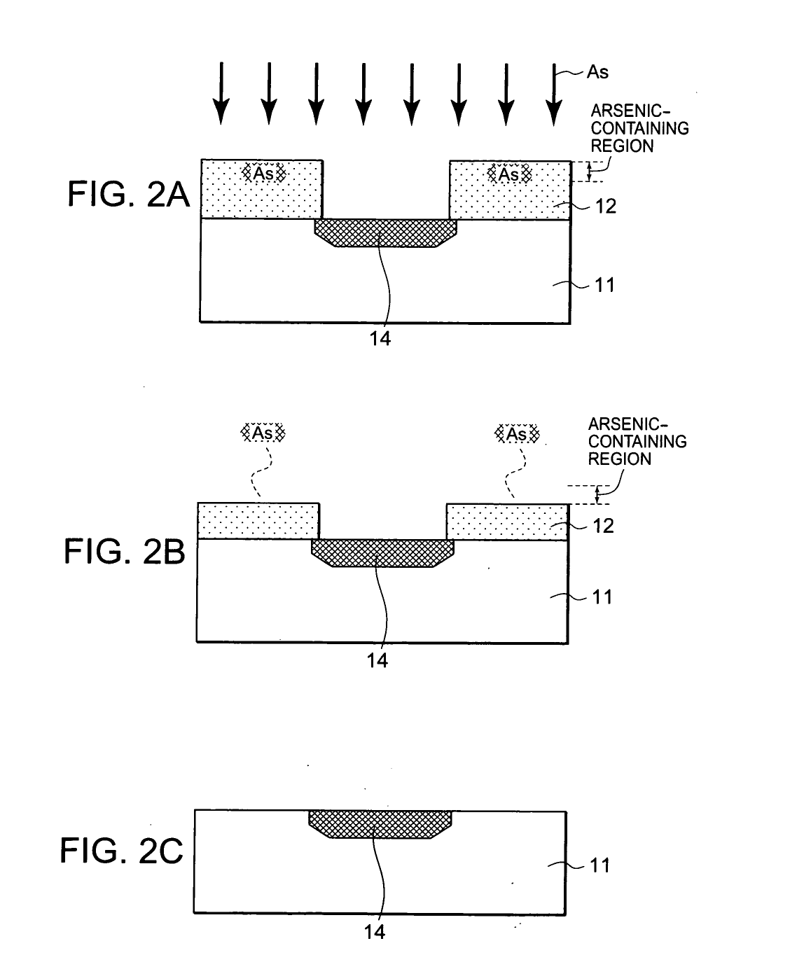

FIGS. 1 and 2 are cross-sectional drawings illustrating a manufacturing method of a semiconductor device, step by step, which has an N-type diffusion region related to the first embodiment.

First, as shown in FIG. 1A, a silicon nitride film 12 is formed over a silicon substrate 11 which is a semiconductor substrate. Film deposition of the silicon nitrite film 12 is performed by using an LPCVD technique, for instance, at a deposition temperature of 760° C. in SiH₂Cl₂ and HN₃ gas atmosphere. Since the silicon nitride film 12 is used as a mask during selective implantation of arsenic in the subsequent process, it is necessary that the film thickness be at least greater than the mean projected range of arsenic. Then, a photoresist 13 is formed over the silicon nitrite film 12.

Next, as shown in FIG. 1B, patterning of the photoresist 13 is performed by using a typical lithography technique and a hole opening is formed in the photoresist 13.

Next, as shown in FIG. 1C, the silicon nitride film 12 is selectively removed by dry etching using the patterned photoresist 13 as a mask, resulting in a part of silicon substrate 11 being exposed. As a result, a mask of the silicon nitride film 12 used during selective implantation of arsenic which is an N-type impurity is fabricated. Moreover, the photoresist 13 which was used for a mask during dry etching this silicon nitride film 12 is removed by ashing.

Next, as shown in FIG. 2A, arsenic (As) is selectively injected into the entire surface by an ion implantation technique. As a result, arsenic is injected into the region where the silicon substrate 11 is exposed at the hole opening of the silicon nitrate film 12, resulting in formation of an N-type impurity diffusion region 14. Moreover, at the same time, arsenic is injected into the silicon nitride film 12 used for a mask until a predetermined depth and an arsenic-containing region (arsenic including region) is formed in the silicon nitride film 12. When selective implantation of arsenic is performed under the conditions of an implantation energy of 40 keV and a dosage of 5×10¹⁵ cm⁻², arsenic is injected down to a depth of about 60 nm from the surface of the silicon nitride film 12.

Next, as shown in FIG. 2B, dry etching is performed on the silicon nitride film 12 down to the depth where arsenic is injected by selective implantation of arsenic (first etching process). The first etching process is performed on the region in the silicon nitride film 12 where arsenic is included for the purpose of removing arsenic included in the silicon nitride film 12. Specifically, if arsenic included in the silicon nitride film 12 is completely removed by the first etching process, no arsenic is included in the silicon nitride film 12 after finishing the first etching process. This dry etching is performed using gases in a fluorine system gaseous atmosphere, for instance, 70 sccm of NF₃, 1800 sccm of O₂, and 500 sccm of N₂ and under the pressure of 25 Pa.

Moreover, the end point of dry etching can be controlled by using, for instance, time. According, to the conditions of the selective implantation of arsenic, it can be calculated how deep arsenic is injected into the silicon nitride film and the value where a small amount of margin is added to the calculation result can be set to be the amount (depth) to be etched by dry etching. In the prior test, by performing dry etching with the set depth while measuring time, the time required by etching (etching time) is determined, so that it can be used for detecting the end point of dry etching. As a result, dry etching of the silicon nitride film 12 can be suitably performed until the depth where arsenic is included. For instance, in the above-mentioned condition, it only has to be done for about 1 minute.

Arsenic included in the etched silicon nitride film 12 is released in the etching chamber by dry etching this silicon nitride film 12. Moreover, a part of arsenic forms a reaction product (SiₓN_{y}As_{z}) which includes Si, N, and As, resulting in its being released in the etching chamber. Arsenic and the reaction product including arsenic which are released in the etching chamber are finally exhausted outside the etching chamber.

As shown in FIG. 2C, the rest of the silicon nitride film 12 is etched by wet etching using phosphoric acid (second etching process). At this time, when arsenic included in the silicon nitride film 12 is completely removed in the first etching process, the reaction product including arsenic is not produced because arsenic is never eluted in the wet etching liquid. Wet etching is performed by dipping it, for instance, in H₃PO₄ solution with a concentration of 86% which has been heated up to 160° C. for a predetermined time. As a result, all of the silicon nitride film 12 which has become unnecessary is removed.

In the following process, recovery of damage received by crystals of the silicon substrate 11 and activation of ions are accomplished by annealing (heat treatment). Thus, an N-type impurity diffusion region 14 is formed over the silicon substrate 11.

As mentioned above, in the first embodiment of the present invention, arsenic which is an N-type impurity is selectively injected into the region where silicon substrate 11 is exposed using the silicon nitride film 12 having a hole opening as a mask, resulting in an N-type diffusion region 14 being formed. At this time, the silicon nitride 12 used as a mask during selective implantation of arsenic is removed by the two-step processes of dry etching (first etching process) and wet etching (second etching process). In the first etching process performed at the beginning, etching is performed on the arsenic-containing region in the silicon nitride film 12. In the second etching process performed subsequent thereto, the rest of the silicon nitride film 12 is removed without the attendant plasma damage. If arsenic included in the silicon nitride film 12 could be completely removed by the first etching process, the reaction product (particles) including arsenic, etc. is not produced in the wet etching liquid in the second etching process. As a result, in various manufacturing processes of a semiconductor device performed subsequent to the wet etching process, it becomes possible to suppress the danger where the in-process discrepancies are caused by the particles, resulting in an improvement of productivity being obtained. Moreover, since contaminations in the wet etch bath can be suppressed, reuse of the wet etching liquid becomes possible. As a result, reduction of the manufacturing cost of the semiconductor device becomes possible.

Moreover, when dry etching using plasma is generally performed, one must pay attention to the plasma damage which is given to those regions which are exposed to plasma, except for the region being etched. The longer the time for performing dry etching, the greater this plasma damage becomes. Therefore, where plasma damage has to be taken into consideration, one should refrain from the use of dry etching as much as possible. As explained above, etching the silicon nitride film 12 is performed combining the first etching process where dry etching is used with the second etching process where wet etching is used. The reason why the entire silicon nitride film 12 is not etched only by the first etching process, where dry etching is used, is due to this plasma damage being taken into consideration.

If the case is assumed where all of the etching the silicon nitride film 12 is performed by dry etching, the N-type diffusion region 14 which is the region except for the region being etched, which is exposed to plasma, gets very serious plasma damage. Therefore, even one attempts a recovery using a subsequent heat treatment, it cannot be expected that the plasma damage obtained is sufficiently recovered. On the other hand, since dry etching is used only for a part of the etching of the silicon nitride film 12 in the first embodiment, even if the N-type diffusion region 14 exposed to the plasma gets plasma damage by dry etching, it can be suppressed to be relatively small. Such relatively small plasma damage can be sufficiently recovered by a heat treatment of the N-type diffusion region 14 afterwards.

Moreover, when there is an attempt to make the plasma damage to the N-type diffusion region 14 as small as possible, control of the implantation energy of arsenic also becomes necessary. Specifically, since the depth of arsenic injected into the silicon nitride film 12 changes with implantation energy, the depth where arsenic is injected into the silicon nitride film 12 can be controlled by controlling this implantation energy. As a result, it becomes possible to make the time for using dry etching even shorter.

In the explanation of the aforementioned first etching process, it was explained that the arsenic-containing region in the silicon nitride film 12 is removed. However, as a matter of course, it is not limited to removal of all arsenic contained in the silicon nitride film 12. Specifically, even if some arsenic remains in the silicon nitride film 12 after the first etching process, the amount of arsenic which elutes in the wet etching liquid can be decreased, so that the amount of the reaction product (particles) including arsenic which is produced can be suppressed. That is, the degree of contamination in the wet etching liquid becomes lower by far than the prior art, and the number of times the wet etching liquid can be reused is drastically increased.

### Second Embodiment

Next, the present invention is illustrated by using the following examples. In the second embodiment of the present invention, an example of a manufacturing method for a memory cell transistor of a split-gate type nonvolatile memory which is a kind of electrically erasable nonvolatile semiconductor memory device.

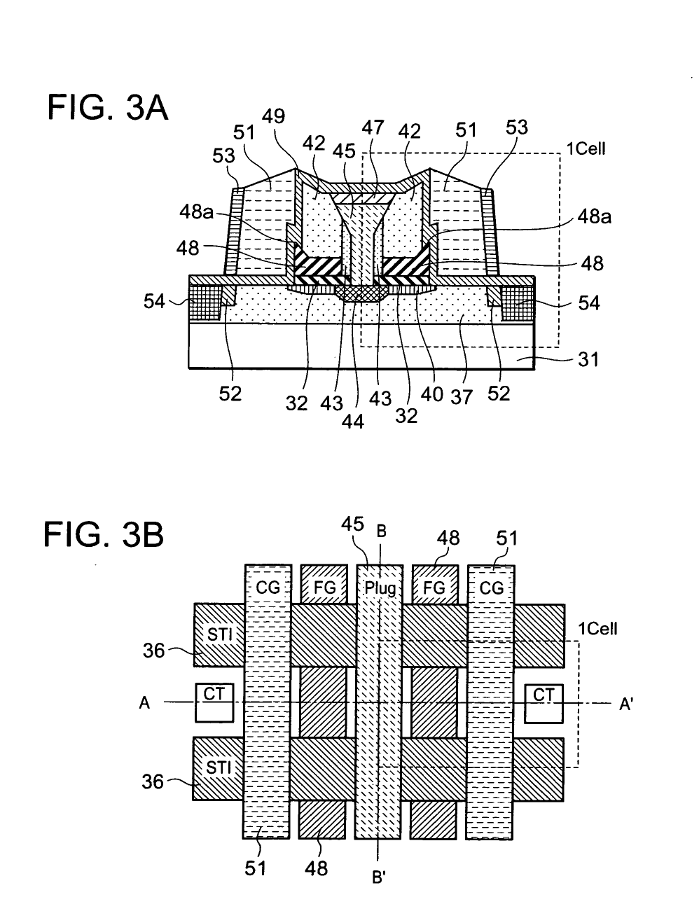

FIG. 3A is a cross-sectional drawing illustrating a structure of a memory cell transistor of the second embodiment, and FIG. 3B is a plane drawing (plane layout) as seen from above. The cross-sectional drawing of FIG. 3A corresponds to the cross-section at A-A′ in FIG. 3B. Moreover, FIG. 3A and FIG. 3B illustrate two memory cell transistors in which the memory cell transistors are arranged symmetrically relative to the common plug 45. The part surrounded by the dotted line corresponds to one memory cell transistor (1 cell) and a memory of one bit of data is possible.

As shown in FIG. 3, a P well 37 which is a P-type well, a first source/drain diffusion region 44 which is an N-type impurity region and which will be a source or drain, and a second source/drain diffusion region 54 are formed in the silicon substrate 31 which is a semiconductor substrate, respectively. A plug 45 is formed over the first source/drain diffusion region 44 and a first plug insulating film 43 is formed on both sides of the plug 45.

Moreover, at both sides of the plug 45, a floating gate (FG) 48 is formed sandwiching the first plug insulating film 43. Specifically, the first plug insulating film 43 plays a role in performing electrical isolation between the plug 45 and FG 48. A gate insulating film 32 is formed between the FG 48 and the silicon substrate 31. The FG 48 overlaps a part of the first source/drain diffusion region 44, and the FG 48 and the first source/drain diffusion region 44 make capacitive coupling through the gate insulating film 32. Moreover, a spacer 42 which is an insulating film is formed over the FG 48. Furthermore, at the edge of the FG 48, which does not make contact with the first plug insulating film 43, there is contact with the tunneling insulating film 49. Therefore, the FG 48 is surrounded by the first plug insulating film 43, the gate insulating film 32, the spacer 42, and the tunneling insulating film 49, and is electrically isolated from outside. The threshold voltage of the memory cell transistor changes depending on the electric charge stored in this FG48.

Moreover, a control gate (CG) 51 is formed at the location opposite the plug 45 against the FG 48. Moreover, a part of the CG 51 is formed to cover the pointed shaped Tip part 48a which lies from FG 48 to CG 51 and the major part of the remainder is formed at the region over the silicon substrate 31. The tunneling insulating film 49 exists not only between the CG 51 and the FG 48 but also between the CG 51 and the silicon substrate 31. Thus, a memory cell transistor of the third embodiment has a memory structure which can prevent error occurrence caused by excessive erasure.

Moreover, in a memory cell transistor of the split gate type nonvolatile memory shown in FIG. 3A, the FG 48, CG 51, and the plug 45, the first plug insulating film 43, and the spacer 42 are formed in self-alignment. These structural features appear as a result of the peculiar manufacturing process which is described later.

As shown in FIG. 3B, the plug 45, the FG 48, and CG 51 are formed in the direction perpendicular to the cross-sectional (A-A′) direction of FIG. 3A, and the FG 48 and CG 51 are arranged symmetrically relative to the plug 45. On the other hand, a Shallow Trench Isolation (STI) 36 which is an isolation region is formed in the direction parallel to the cross-sectional (A-A′) direction of FIG. 3A to isolate the elements electrically.

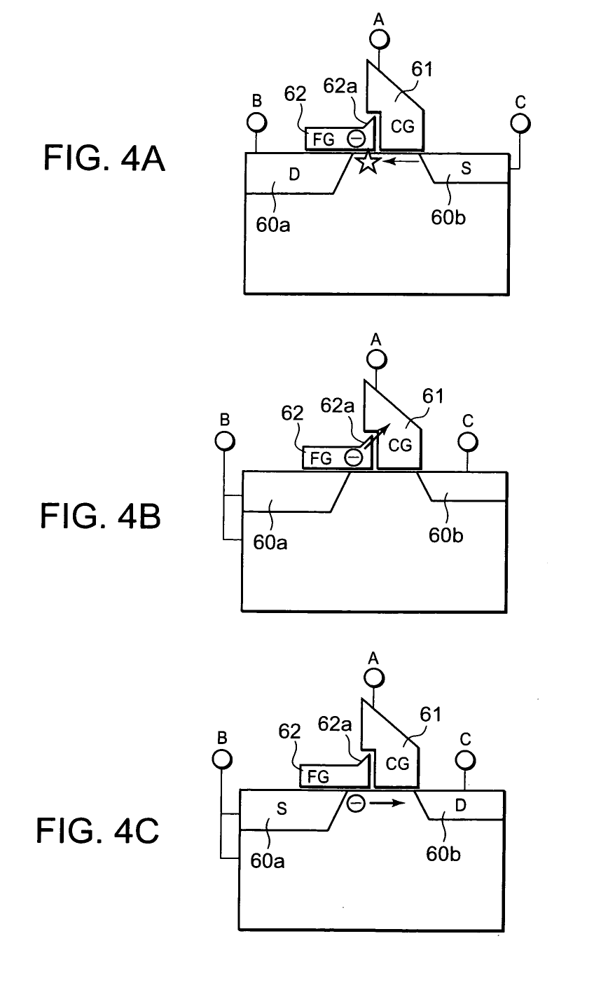

Next, using FIG. 4A to FIG. 4C, operation of the memory cell transistor of the second embodiment will be illustrated. FIG. 4A, FIG. 4B, and FIG. 4C illustrate a writ operation, an erasure operation, and a read operation, respectively. In the explanation of the operations, FIG. 4A to FIG. 4C show only one memory cell transistor for simplification, and structures except for the first source/drain diffusion region 60a, the second source/drain diffusion region 60b, the CG 61, the FG 62, and the Tip part 62a are omitted.

As shown in FIG. 4A, writing is carried out by the Channel Hot Electron (CHE) method. At this time, the first source/drain diffusion region 60a works as a drain and the second source/drain region 60b works as a source, respectively. For instance, a voltage of +1.8 V is applied to the CG 61 (tap A); a voltage of +9.5 V is applied to the first source/drain diffusion region 60a (tap B); and a voltage of +0.25 V is applied to the second source/drain diffusion region 60b (tap C). Electrons released from the second source/drain diffusion region 60b are accelerated by the high electric field in the channel region to be CHE. Especially, the electric potential of the FG 62 becomes higher by capacitance coupling between the first source/drain diffusion region 60a and the FG 62, and a strong electric field is generated at the narrow gap between the CG 61 and the FG 62. High energy CHE generated by the strong electric field is injected into the FG 62 through the gate insulating film. Such injection is called source side injection (SSI). According to SSI, the electron injection efficiency is improved; thereby, it becomes possible to decrease the applied voltage. The threshold voltage of the memory cell transistor is increased by injecting electrons into the FG 62.

As shown in FIG. 4B, erasure is performed by the fowler nordheim (FN) tunnel method. For instance, a voltage of +11.5 V is applied to the CG 61 (tap A) and the voltage applied to the first source/drain diffusion region 60a, the second source/drain diffusion region 60b, and the substrate (tap B and tap C) is controlled to be 0 V. As a result, an FN tunneling current flows by applying a high electric field to the tunnel insulating film between the CG 61 and the FG 62. Therefore, electrons in the FG 62 are drawn through the tunnel insulating film to the CG 61. Especially, in the periphery of the Tip part 62a of the FG 62, a high electric field is generated because of the pointed shape thereof, and electrons in the FG 62 are mainly released from the Tip part 62a to the CG 61. It can be said that the Tip part 62a where a high electric field is generated improves the drawing efficiency of electrons. The threshold voltage of the memory cell transistor is decreased by drawing electrons from the FG 62.

When the threshold voltage related to the FG 62 becomes negative due to excessive erasure, generation of a channel may always occur at the lower part of the FG 62. However, since a CG 61 is also provided over the channel region, one can prevent the memory transistor from being ON all the time. Thus, the memory transistor of the second embodiment has an advantage which prevents the excessive erasure errors.

As shown in FIG. 4C, during reading, the first source/drain diffusion region 60a and the second source/drain diffusion region 60b function as the source and drain, respectively. For instance, a voltage of +1.8 V is applied to the CG 61 (tap A); a voltage of +1 V is applied to the second source/drain diffusion region 60b (tap C); and a voltage applied to the first source/drain diffusion region 60a and the substrate (tap B) is controlled to be 0 V. In the case of an erasure cell, the threshold voltage is small and a read current Icell flows. On the other hand, in the case of a write (program) cell, the threshold voltage is high and a read current Icell hardly flows. One can judge whether it is the program cell or the erasure cell by detecting the read current Icell.

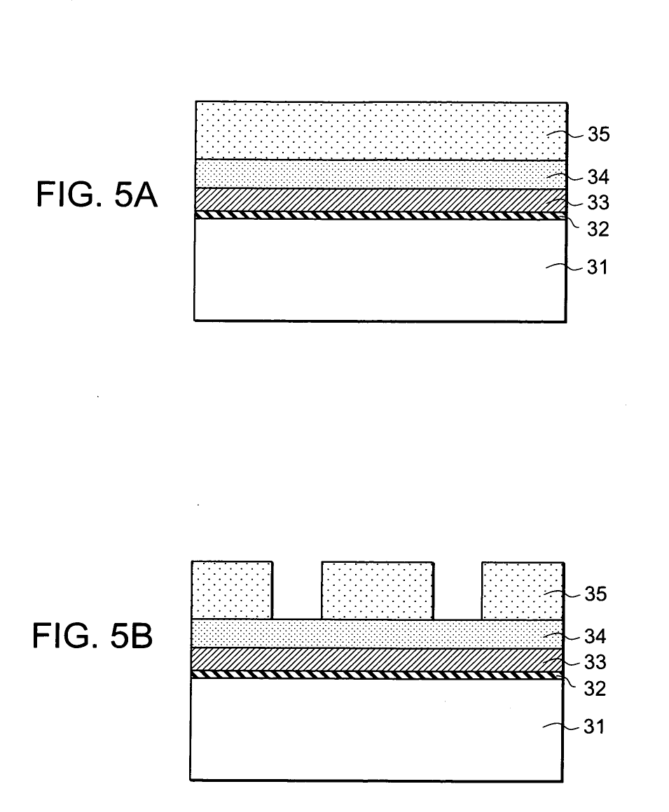

FIG. 5 to FIG. 29 are the cross-sectional drawings illustrating a manufacturing method of a memory cell transistor of a split gate type nonvolatile memory of the second embodiment. Drawing A in each figure shows a cross-section along A-A′ in FIG. 3B and drawing B in each figure shows a cross-section along B-B′ in FIG. 3B.

First, as shown in FIG. 5, a gate insulating film (for instance, oxide film) is formed over the silicon substrate 31. Then, a FG thin film (for instance, polysilicon thin film) 33 which is a conducting film is formed over the gate insulating film 32, and a field insulating film (for instance, nitride film) 34 is formed over the FG thin film 33. After that, a first photoresist film 35 is coated over the field insulating film 34 and, as shown in FIG. 5B, the first photoresist film 35 is patterned by using a lithography technique and a hole opening is formed.

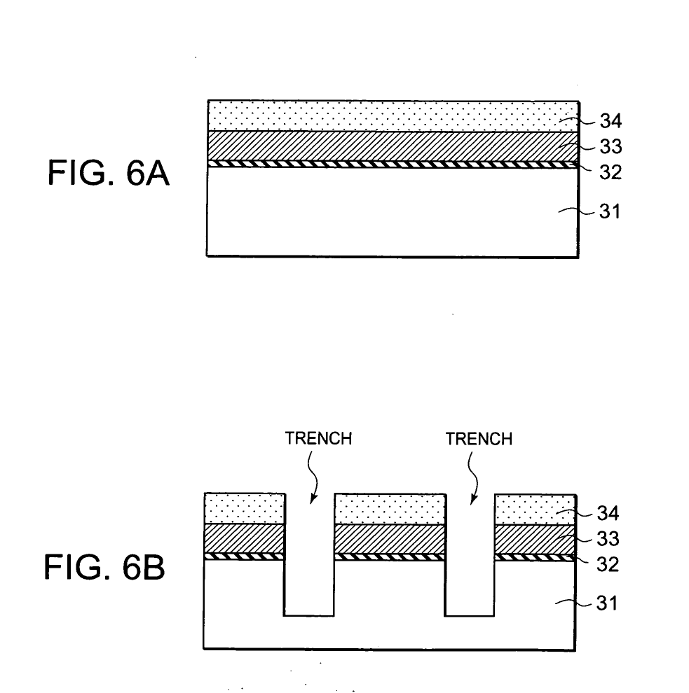

Next, as shown in FIG. 6B, anisotropic dry etching is performed on the surface part of the field insulating film 34, the FG thin film 33, the gate insulating film 32, and the silicon substrate 31 using the patterned first photoresist film 35 as a mask, resulting in a trench being formed.

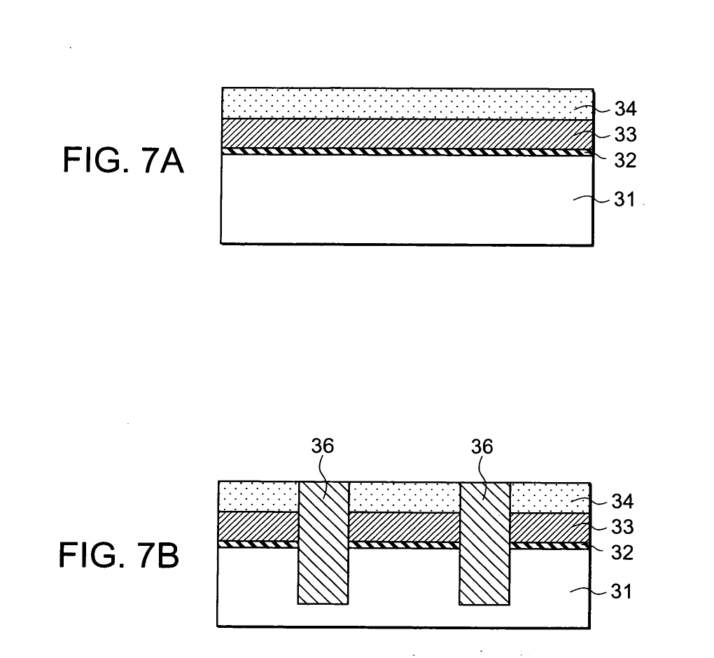

Next, as shown in FIG. 7B, an oxide film is filled in the trench part by using a typical STI process technique and the isolation region STI 36 is formed.

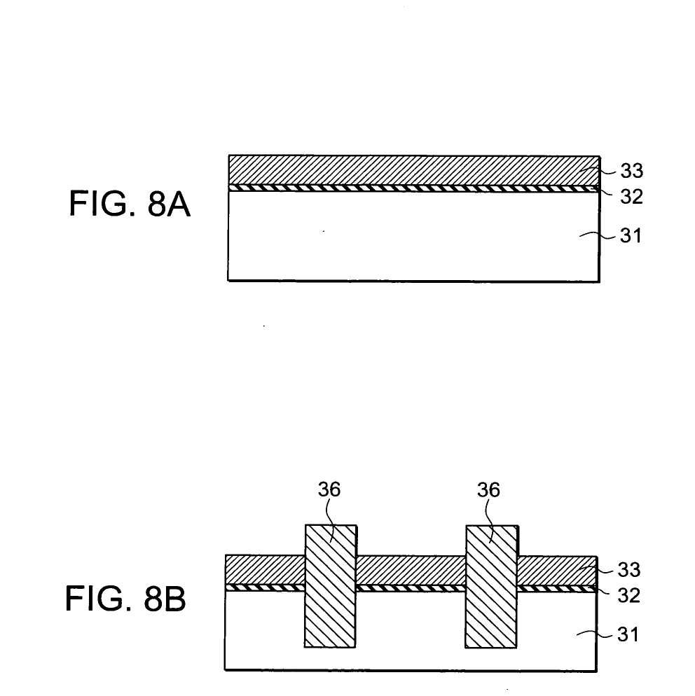

Next, as shown in FIG. 8, the field insulating film 34 is removed by wet etching.

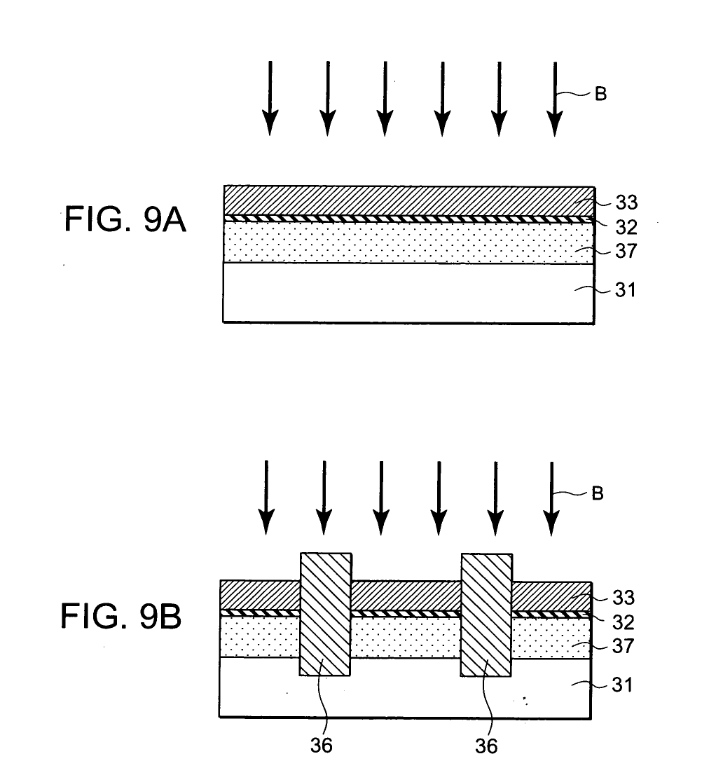

Next, as shown in FIG. 9, ion implantation of a P-type impurity (for instance, boron (B)) is performed on the entire area, resulting in a P well 37 being formed in the silicon substrate 31.

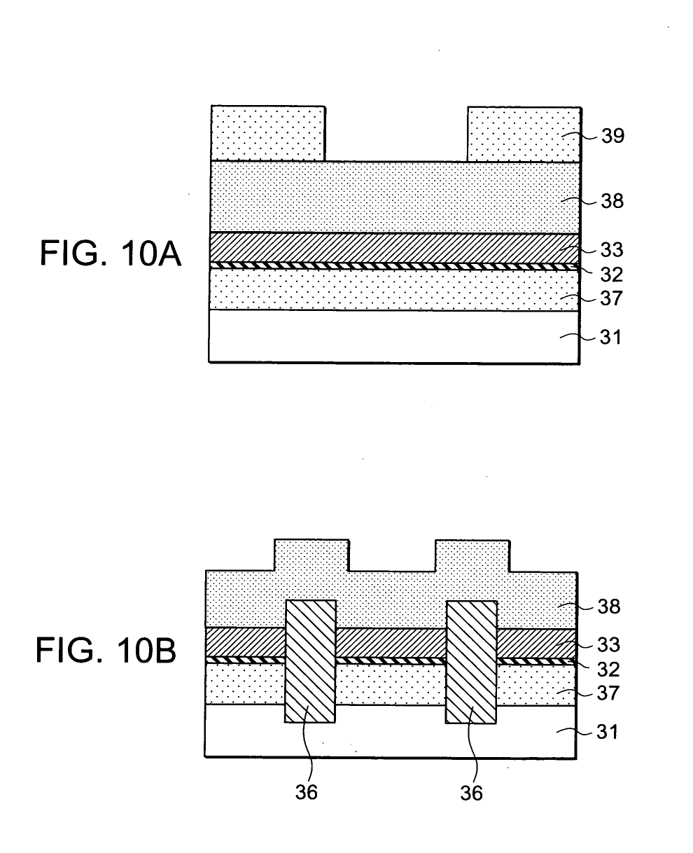

Next, as shown in FIG. 10, a FG silicon nitride film 38 is formed over the FG thin film 33 (in FIG. 10b, the FG thin film 33 and the isolation region STI 36), for instance, at 760° C. and in an atmosphere of SiH₂Cl₂ and NH₃ gas by using a LPCVD technique. Since the FG silicon nitride film 38 is used as a mask during selective implantation of arsenic in the following process, the film thickness is needed to be greater than the mean projected range of arsenic. After that, the second photoresist film 39 is coated over the FG silicon nitrite film 38. As shown in FIG. 10A, the second photoresist film 39 is patterned by a lithography technique, resulting in a mask pattern having a hole opening being formed. At this time, in FIG. 10B, all of the second photoresist film 39 is removed.

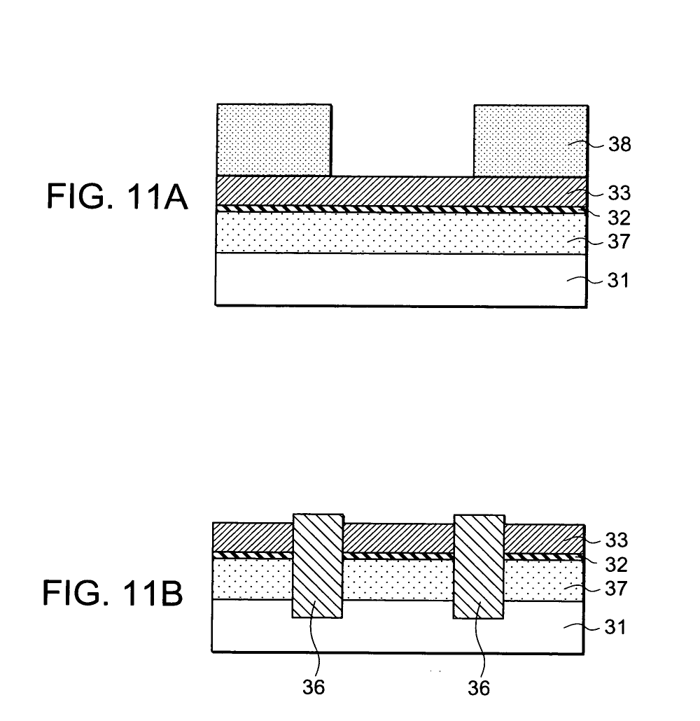

Next, as shown in FIG. 11A, anisotropic dry etching is performed on the FG silicon nitride film 38 using the patterned second photoresist film 39 as a mask, resulting in a hole opening being formed in the FG silicon nitride film 38. Moreover, as shown in FIG. 11B, in the B-B′ cross-section where there is not a mask formed of the second photo resist film 39, all of the exposed FG silicon nitride film 38 is removed by dry etching. At this time, over-etching is performed in order to clearly remove the FG silicon nitride film 38; thereby, from the relationship of the etching selection ratio, some of the isolation region STI 36 is scraped. By comparison with FIG. 10B, it is understand that the ratio where the isolation region STI 36 is projected from the FG thin film 33 becomes smaller.

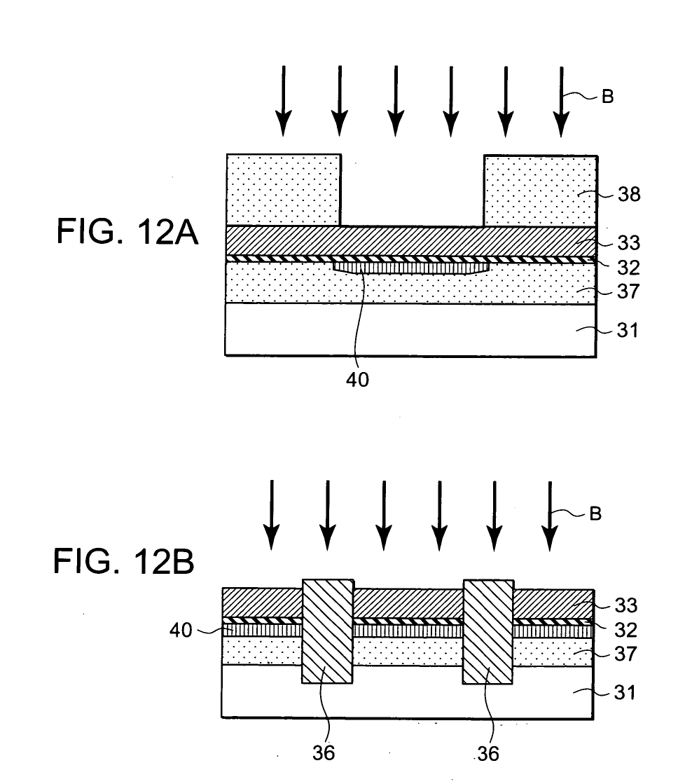

Next, as shown in FIG. 12, ion implantation of a P-type impurity (for instance, boron) is performed on the entire area and a P-type impurity diffusion region 40 for controlling the threshold voltage is formed. In FIG. 12A, selective implantation is performed on the hole opening area of the FG silicon nitride film 38.

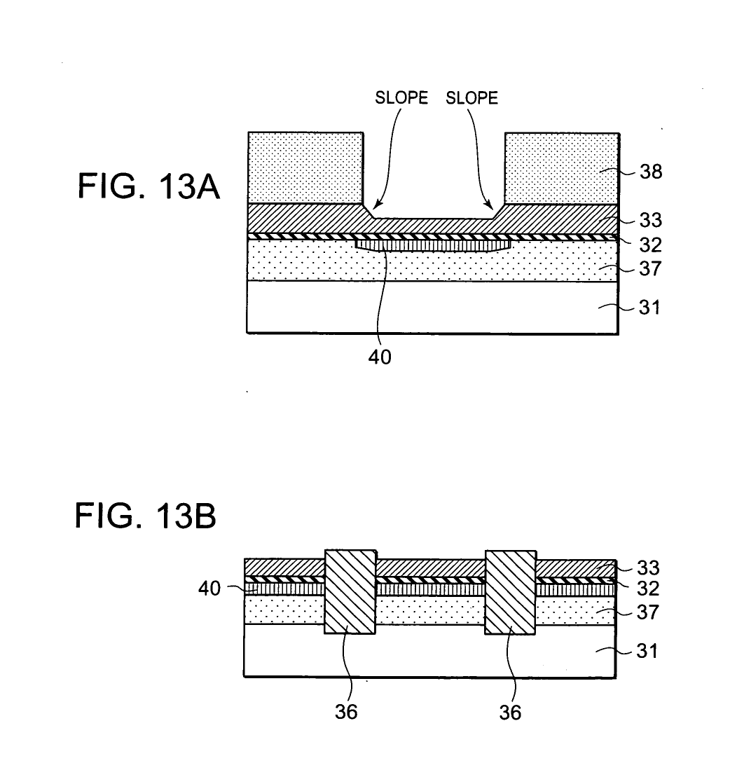

Next, as shown in FIG. 13A, a part of the FG thin film 33 is removed by dry etching using the FG silicon nitride film 38 as a mask. The edge part of the FG thin film 33 which was partially removed has a sloped shape and becomes the Tip part 48a of the FG 48. Moreover, in FIG. 13B, the surface of the FG thin film 33 is completely etched.

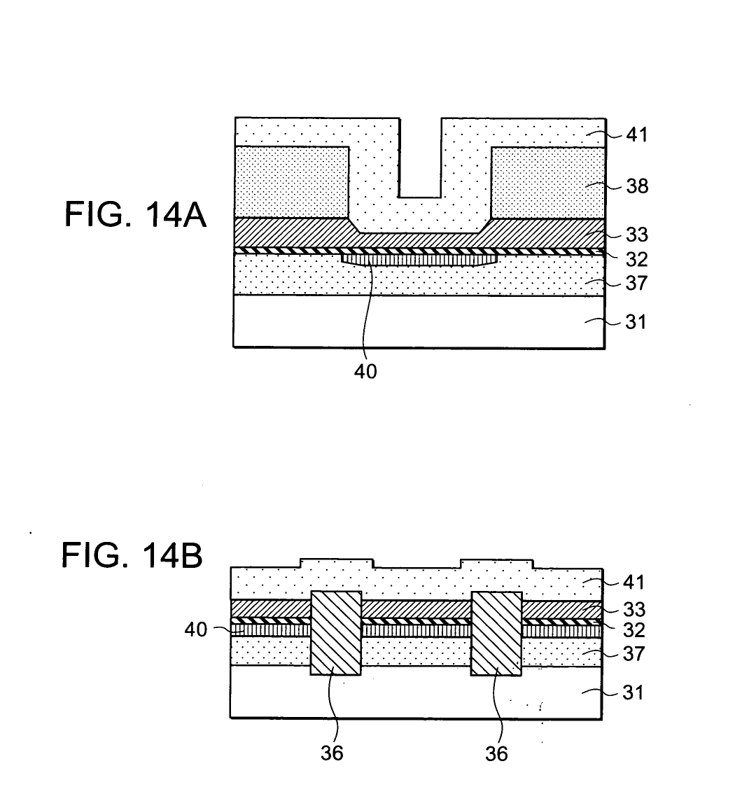

Next, as shown in FIG. 14, a first high temperature oxide film (HTO) 41 is deposited over the entire area by using a CVD technique at 800° C.

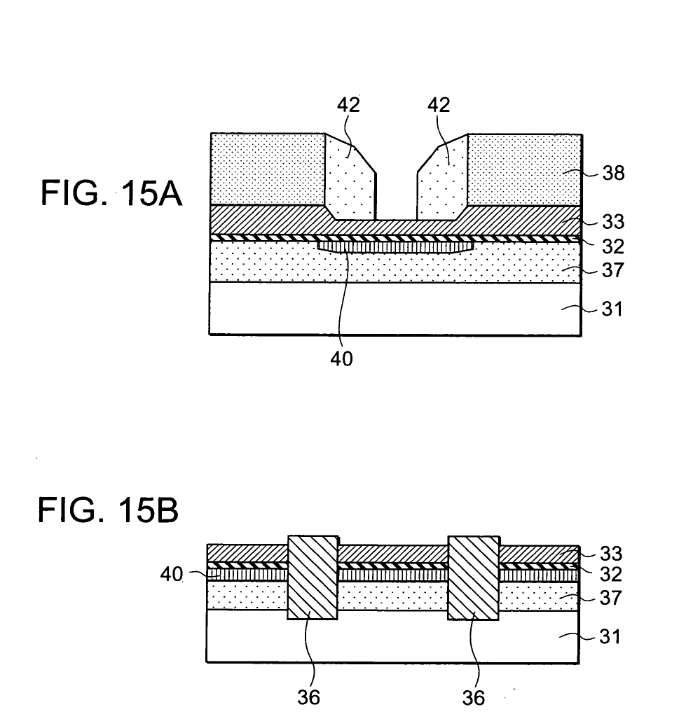

Next, as shown in FIG. 15A, the first HTO 41 is etched back and the first HTO 41 deposited over the FG silicon nitride film 38 and around the center of the hole opening is removed. As a result, a spacer 42 is formed over the sidewall of the FG silicon nitride film 38 in the hole opening. Moreover, since the height of the isolation region STI 36 projecting from the FG thin film 33 in FIG. 15B is not so high, the first HTO 41 dose not remain over the sidewall of the isolation region STI 36 and all of it is removed by etching back.

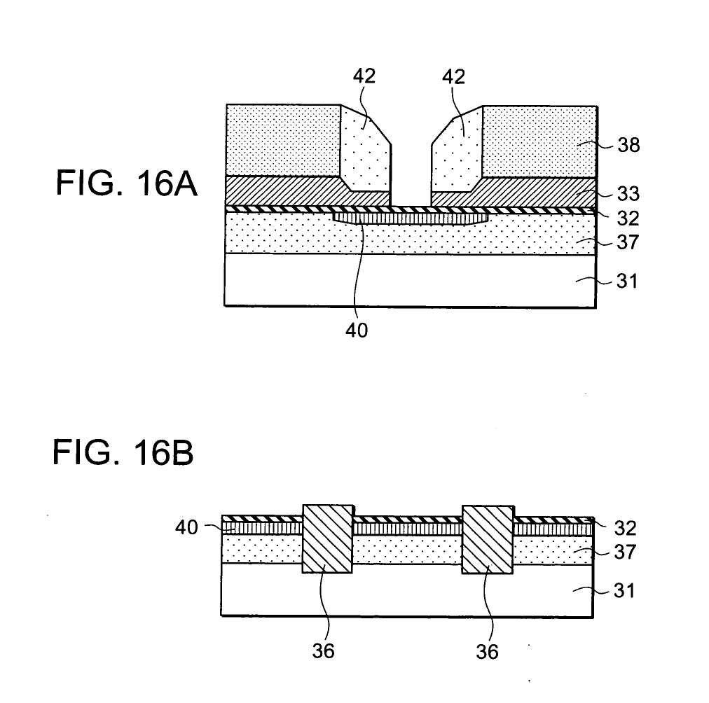

Next, as shown in FIG. 16, the FG thin film 33 is removed by dry etching. Especially, in FIG. 16A, the FG thin film 33 is selectively removed by using the FG silicon nitride film 38 and the spacer 42 as a mask. On the other hand, in FIG. 16B, all of the FG thin film 33 is removed, resulting in the gate insulating film 32 being exposed.

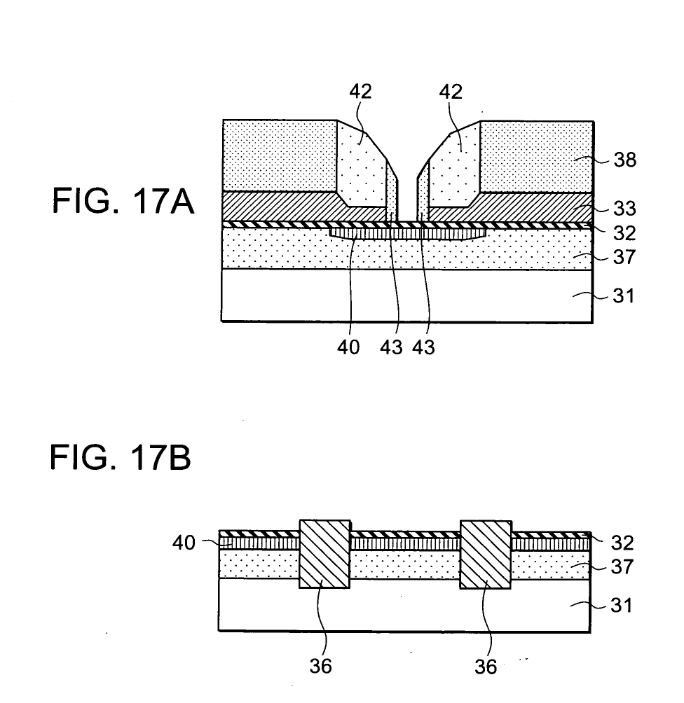

Next, after a second HTO is deposited over the entire surface by using CVD, etching back is performed. As shown in FIG. 17A, a first plug insulating film 43 is formed over the sidewall of the FG thin film 33 and the spacer 42 in the hole opening. In FIG. 17B, the deposited second HTO is completely removed just like the process in FIG. 15B.

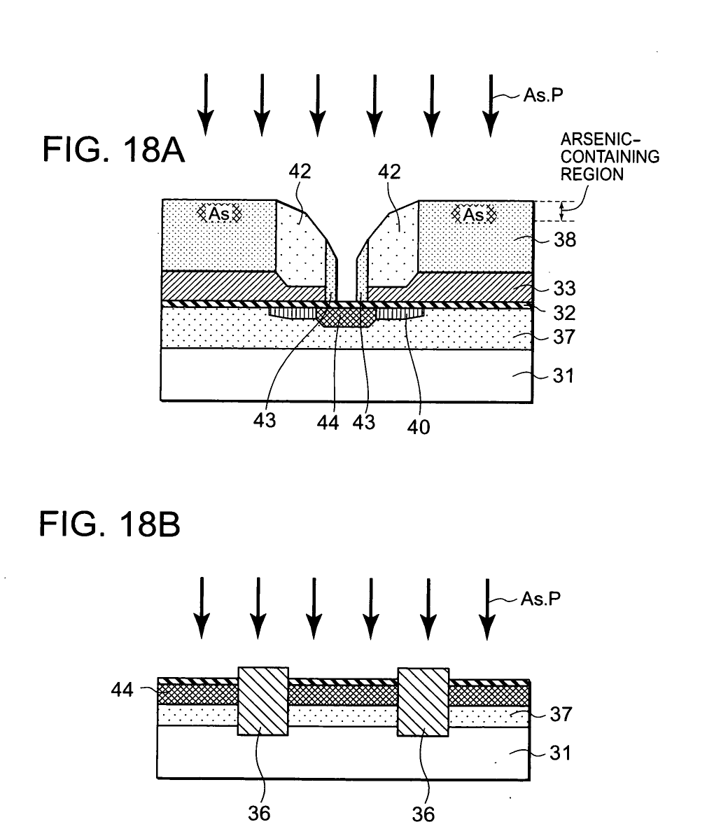

Next, as shown in FIG. 18, ion implantation of arsenic and phosphorus (P) which are N-type impurities is performed on the entire surface under the conditions of an implantation energy of 40 keV and a dosage of 5×10¹⁵ cm⁻² and the first source/drain diffusion region 44 is formed. In FIG. 18A, since selective implantation is performed by using the FG silicon nitride film 38, the spacer 42, and the first plug insulating film 43 as a mask, arsenic is injected down to a predetermined depth in the FG silicon nitride film 38 which was used for a mask. Specifically, the arsenic-containing region (arsenic included region) is formed in the silicon nitride film 38.

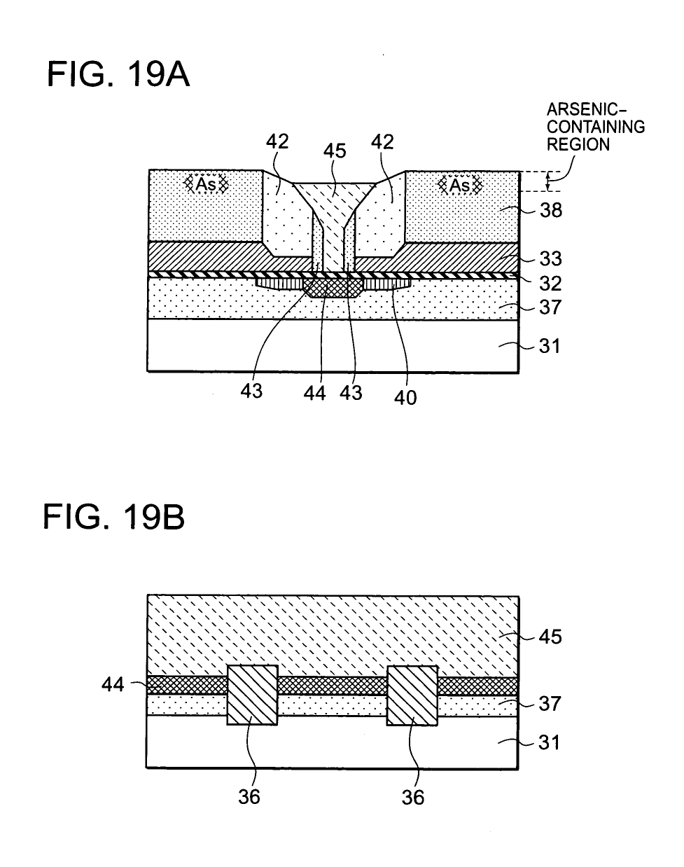

Next, anisotropic dry etching is performed by using the FG silicon nitride film 38, the spacer 42, and the first plug insulating film 43 as a mask, and the gate insulating film 32 at the hole opening is selectively removed in FIG. 19A. On the other hand, in FIG. 19B, the entire gate insulating film 32 is removed. Then, a conducting film (for instance, polysilicon film) is deposited over the entire surface and chemical mechanical polishing (CMP) is performed. After that, as shown in FIG. 19A, the plug 45 where the conducting film is buried is formed by etching back. Moreover, the plug 45 becomes a layered shape as in FIG. 19B.

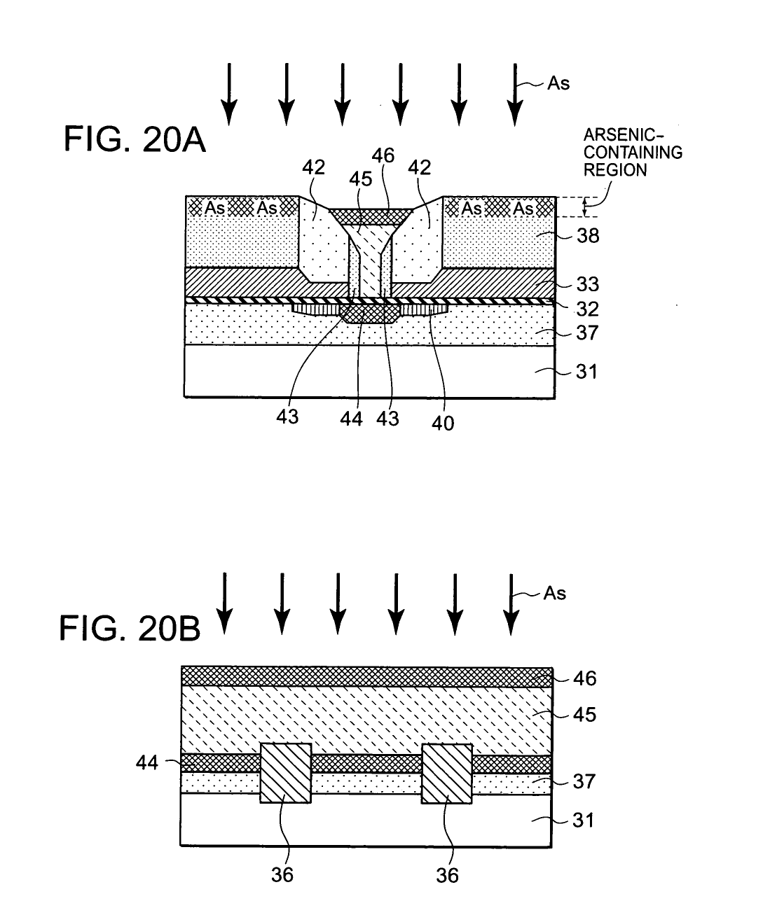

Next, as shown in FIG. 20, for the purpose of acceleration of oxidation of the upper part of the plug 45, ion implantation of arsenic which is an N-type impurity is performed on the entire surface under the conditions of an implantation energy of 40 keV and a dosage of 5×10¹⁵ cm⁻², and an N-type impurity diffusion region 46 is formed. Moreover, as shown in FIG. 20A, arsenic is injected into the FG silicon nitride film 38 by this ion implantation.

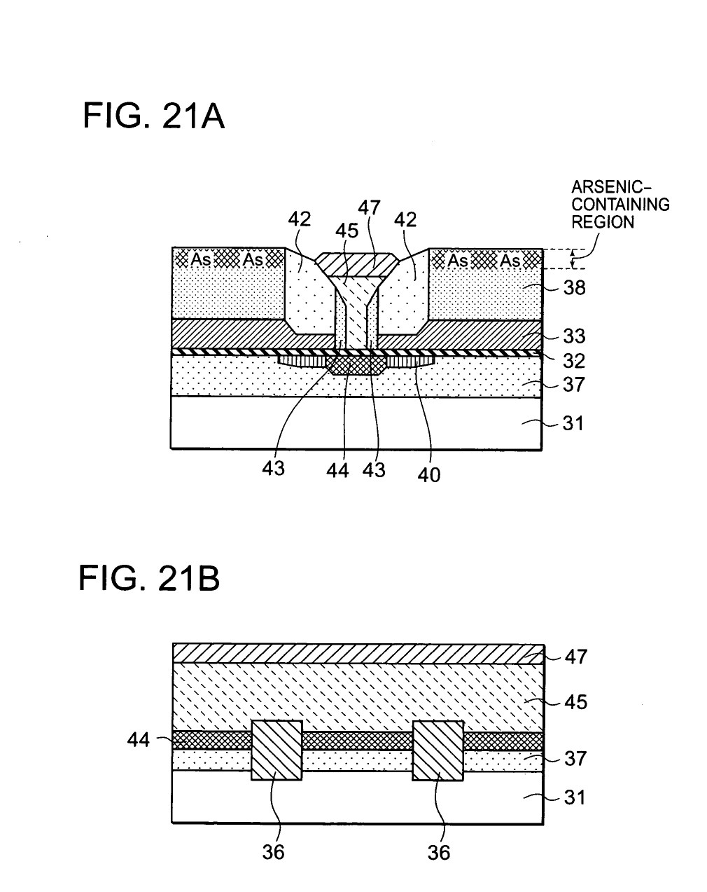

Next, as shown in FIG. 21, a second plug insulating film 47 is formed over the plug 45 by a thermal oxidation treatment.

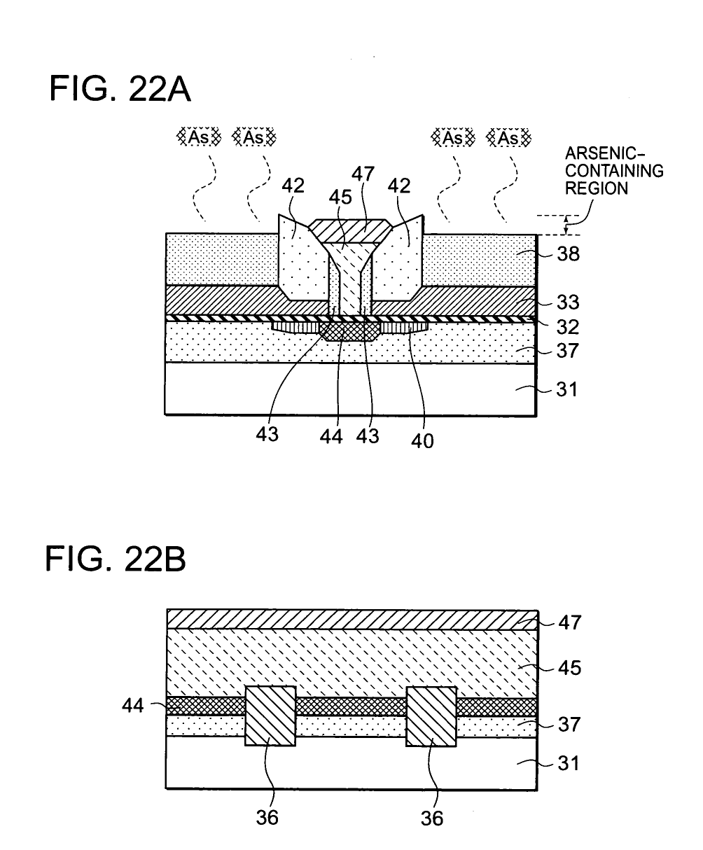

Next, dry etching is performed on the FG silicon nitride film 38 using gases in a fluorine system gaseous atmosphere, for instance, 70 sccm of NF₃, 1800 sccm of O₂, 500 sccm of N₂ and under a pressure of 25 Pa (first etching process). As shown in FIG. 22A, in this dry etching, etching is performed on the FG silicon nitrite film 38 until the depth where the arsenic is injected. Specifically, for the purpose of removing arsenic contained in the FG silicon nitride film 38, etching is performed on the arsenic including region in the FG silicon nitride film 38. The detection of the end point of dry etching is done in the same way as the first embodiment.

Arsenic included in the etched FG silicon nitride film 38 is released in the etching chamber by this dry etching. A part thereof forms a reaction product (SiₓN_{y}As_{z}) which includes Si, N, and As. Finally, arsenic and the reaction product including arsenic are exhausted outside the etching chamber.

Moreover, in this dry etching, the second plug insulating film 47 exposed in the etching gas atmosphere is etched at the same time. However, since the time required for this dry etching becomes the relatively short etching time until the depth where arsenic is injected, the amount of etching of the second plug insulating film 47 can be controlled to be the amount of etching within an acceptable level. Similarly, since the spacer 42 exposed in the etching gas atmosphere is formed of the first HTO 41, the selection ratio with the FG silicon nitride film 38 is sufficiently high, so that etching of the spacer 42 hardly proceeds.

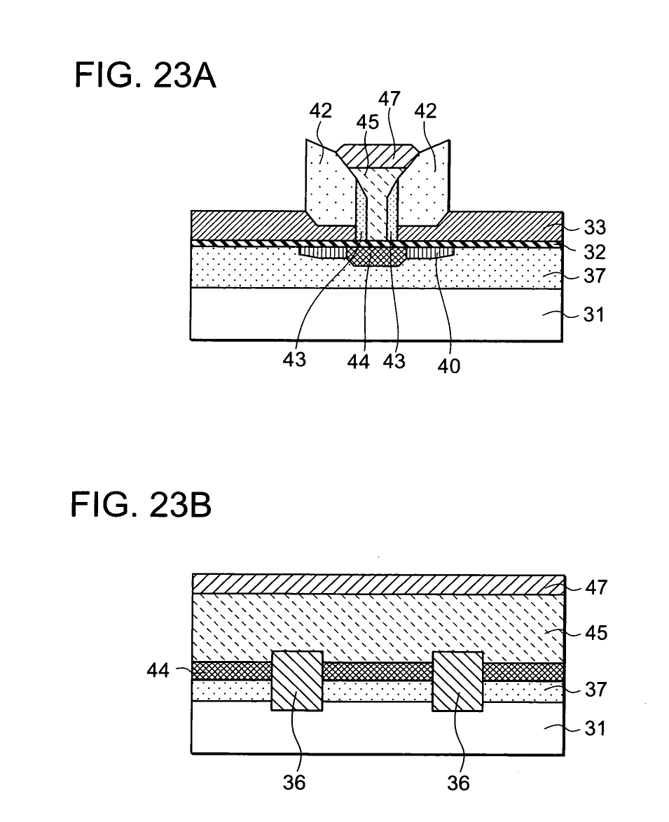

Next, as shown in FIG. 23A, the rest of the FG silicon nitride film 38 is etched by wet etching using phosphoric acid (second etching process). This wet etching is carried out by dipping it in a liquid having, for instance, H₃PO₄ (concentration of 86%) at 160° C. for a predetermined time. As a result, all of the FG silicon nitride film 38 which had become unnecessary is removed. If all of the arsenic included in the FG silicon nitride film 38 is removed in the first etching process, a reaction product (particles) including arsenic is never produced in the wet etching liquid of the second etching process. As a result, contamination of the wet etching liquid hardly occurs.

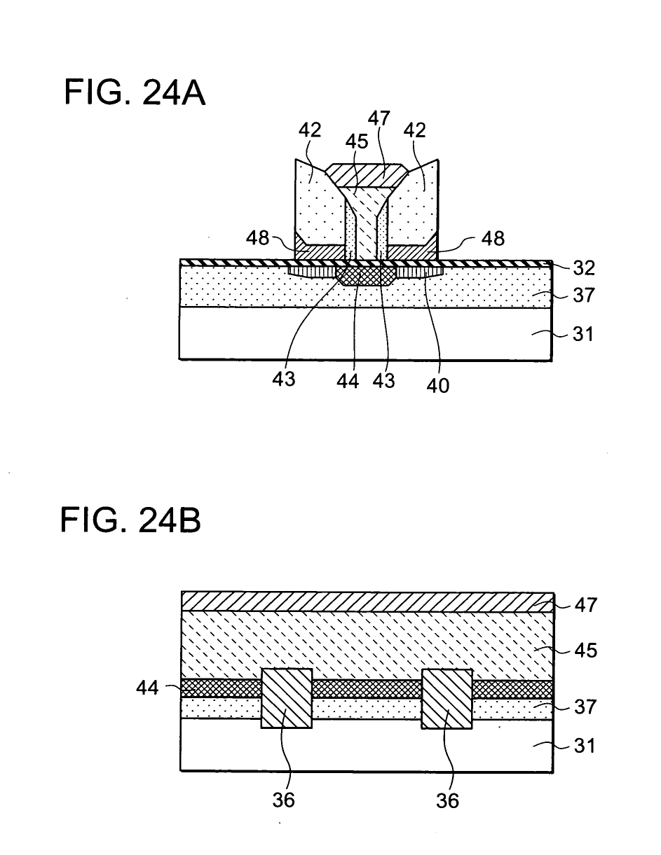

In the second embodiment, the FG silicon nitride film 38 is not always removed only by dry etching (first etching process), and the FG silicon nitride film 38 is removed mainly by wet etching (second etching process). As a result, it is possible to prevent the second plug insulating film 47, which is a region except for region to be etched, from drastically decreasing. On the other hand, if it is assumed that all of the FG silicon nitride film 38 is removed only by dry etching (first etching process), it is not necessary to discuss the contamination of the wet etching liquid. However, since the time required for dry etching becomes longer, there is a possibility that the second plug insulating film 47 is removed by the dry etching. If the second plug insulating film 47 is removed, a problem arises that the plug 45 is etched at the same time in the following etching process of the FG thin film 33 (FIG. 24).

Moreover, there is a case where the side face of the spacer 42 located on the opposite side of the plug 45 is tilted toward the direction moving away from the plug caused by unevenness of the production. In this case, the edge of the tilted spacer 42 acts as a mask, so that it is impossible to remove the FG silicon film 38 completely only by anisotropic dry etching. However, in the second embodiment, since the isotropic wet etching (second etching process) is performed in addition to the anisotropic dry etching (first etching process), the FG silicon nitride film 38 can be completely removed by the isotropic wet etching even in the position where it is easy for the FG silicon nitride film 38 to remain when the anisotropic dry etching is used.

Next, as shown in FIG. 24A, the FG thin film 33 is selectively removed by dry etching using the spacer 42 and the second plug insulating film 47 as a mask. The FG thin film 33 left underneath of the spacer 42 becomes FG 48.

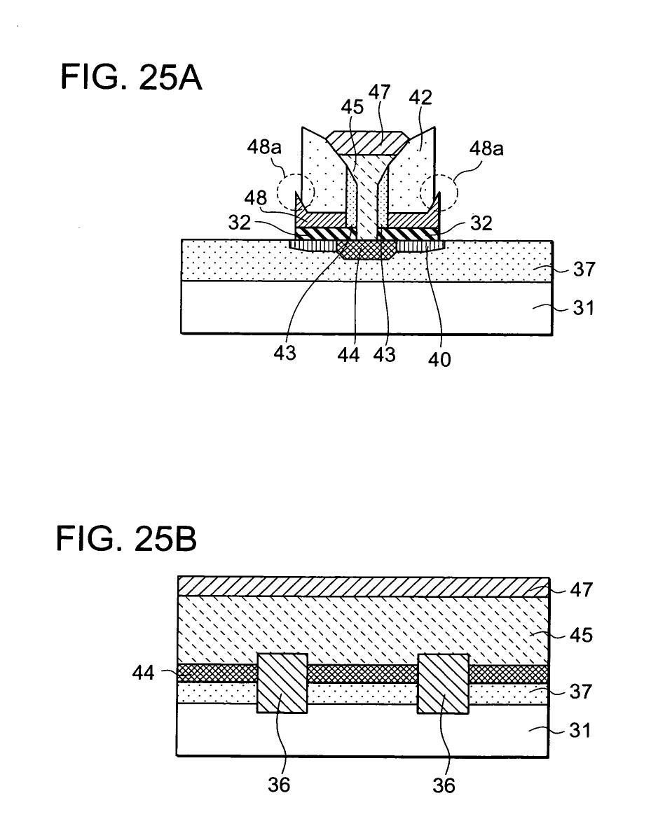

Next, as shown in FIG. 25A, the exposed gate insulating film 32 is removed by wet etching. At this time, the side face of the spacer 42 is etched at the same time and backward (the width of the spacer 42 is decreased). Thus, the Tip part 48a of the FG 48 is exposed.

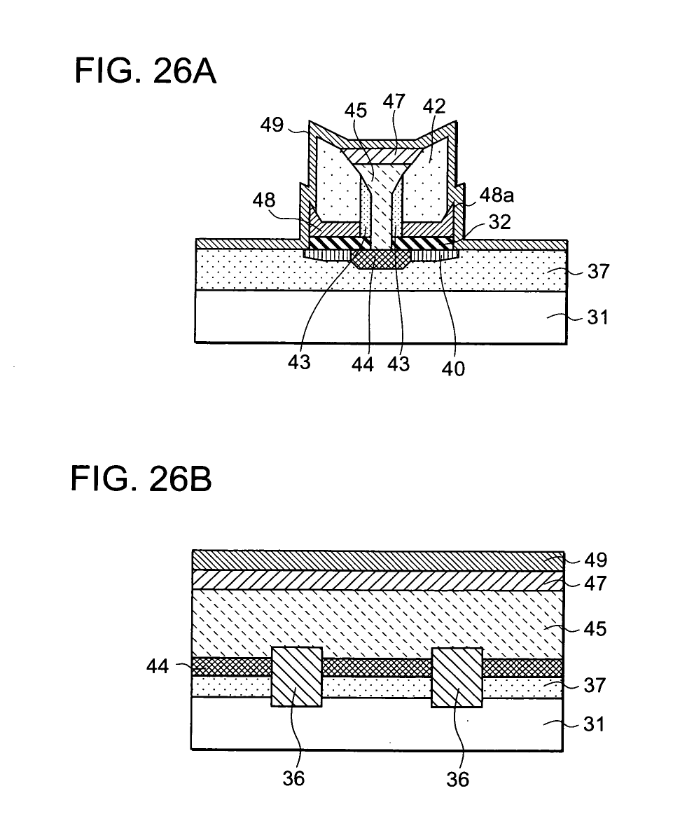

Next, as shown in FIG. 26, a tunnel insulating film (for instance, oxide film) 49 is formed over the entire surface.

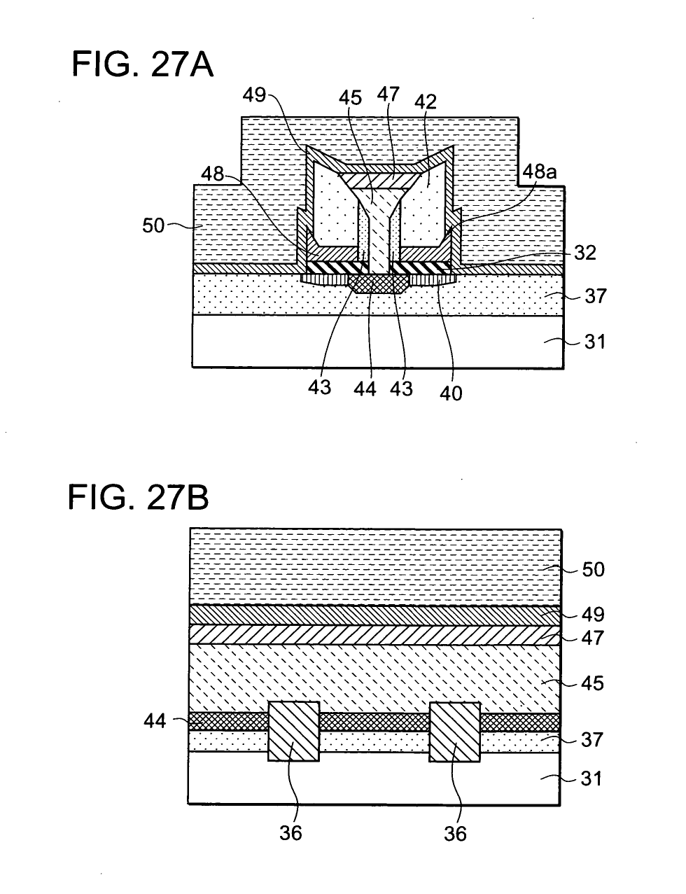

Next, as sown in FIG. 27, a CG film (for instance, polysilicon film) 50 is deposited over the tunnel insulating film 49.

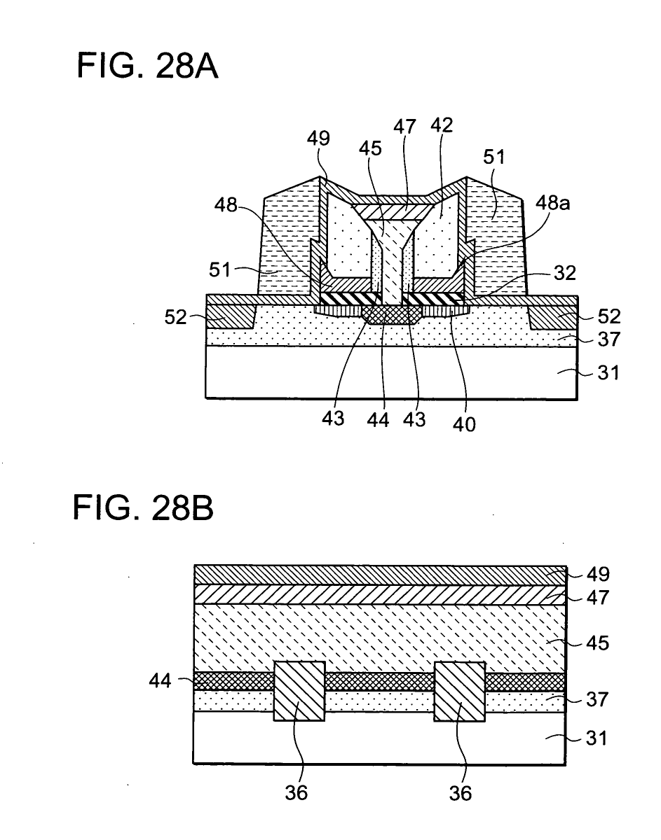

Next, etching back is performed on the CG film 50 and, as shown in FIG. 28A, a CG 51 is formed over the sidewall of the spacer 42 and the FG 48 through the tunnel insulating film 49. Afterwards, an LDD region 52 is formed by ion implantation of arsenic.

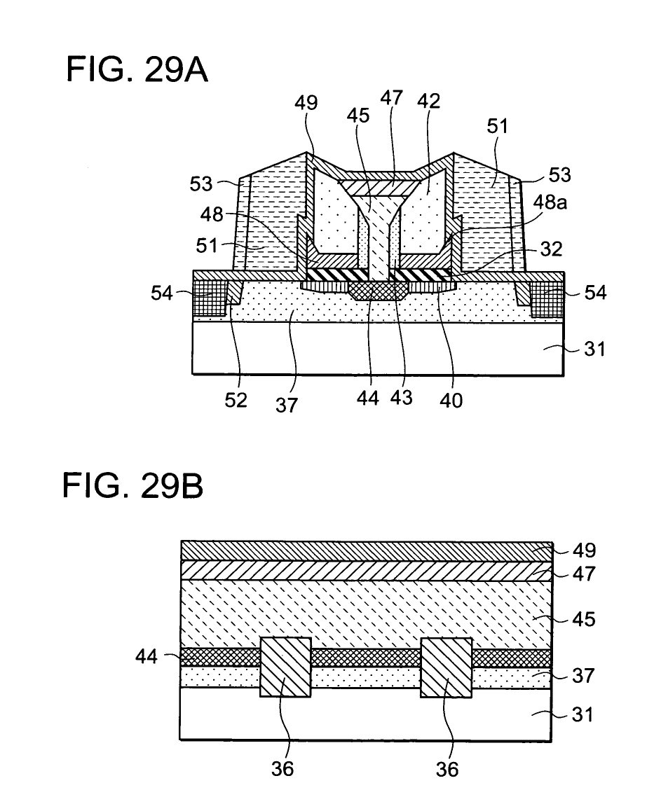

Next, an oxide film is formed over the entire surface and, as shown in FIG. 29A, a CG insulating film 53 is formed over the sidewall of the CG 51 by etching back the oxide film. Afterwards, a second source/drain diffusion region 54 is formed by ion implantation of arsenic and phosphorus. Moreover, during etching back when the CG insulating film 53 is formed, the exposed tunnel insulating film 49 and the second plug insulating film 47 may be removed at the same time. In this case, silicidation of the upper part of the CG 51, the surface of the second source/drain diffusion region 54, and the upper side of the plug 45 may be carried out simultaneously for the purpose of decreasing the resistance.

Thus, a memory cell transistor of the split gate type nonvolatile memory is formed as shown in FIG. 3. According to the manufacturing process described above, usage of a lithography technique can be limited as much as possible and almost all of the components are formed in self-alignment by etching back. Since the frequency of usage of photolithography techniques is reduced, manufacturing becomes easy and it is possible to down-size the cell size.

As mentioned above, in the second embodiment of the present invention, the FG silicon nitride film 38 which was used as a mask during selective implantation of arsenic is etched in the two-step process of dry etching (first etching process) and wet etching (second etching process) the same as the first embodiment of the present invention. In the first etching process which is performed first, etching is performed on the arsenic-containing region in the FG silicon nitride film 38. Moreover, all of the FG silicon nitride film 38 is not always removed by dry etching in the etching time of the first etching process, so that the etching time thereof is relatively short. As a result, it can prevent the second plug insulating film 47 from decreasing drastically. Moreover, in the following second etching process, the rest of the FG silicon nitride film 38 is completely removed. If all of the arsenic included in the FG silicon nitride film 38 could be removed in the first etching process, the reaction product (particles) including arsenic is never produced in the wet etching liquid in the second etching process. Specifically, it becomes possible to suppress the in-process discrepancies which may occur in the following manufacturing processes, and reuse of the wet etching liquid becomes possible.

The same as the first embodiment, the first etching process is not limited to remove all of the arsenic included in the FG silicon nitride film 38 in the second embodiment. If even only a part of the arsenic can be removed by the first etching process, the amount of the reaction product including arsenic produced by the reaction can be suppressed, so that the frequency of reuse of the wet etching liquid can be increased compared with the prior art.

### Third Embodiment

In the third embodiment of the present invention, an example will be explained in which the invention is utilized in the process for removing the silicon nitride film-mask which becomes unnecessary after the process for introducing arsenic ions into the field oxide film (isolation region) in a manufacturing method of a Metal Oxide Semiconductor (MOS) transistor having a silicide structure disclosed in JP-A-1998-50636.

Describing it as a precaution, in the third embodiment, the object into which arsenic is selectively injected is different from those in the first embodiment and the second embodiment, and it is not the semiconductor substrate (silicon substrate) itself but the insulating film (field oxide film) formed over the semiconductor substrate. Specifically, the object into which arsenic is injected depends on for what purpose the selective implantation of arsenic is performed. In the present invention, the object into which arsenic is injected is not limited to the semiconductor substrate itself and, for instance, it may be an insulating film formed over the semiconductor substrate.

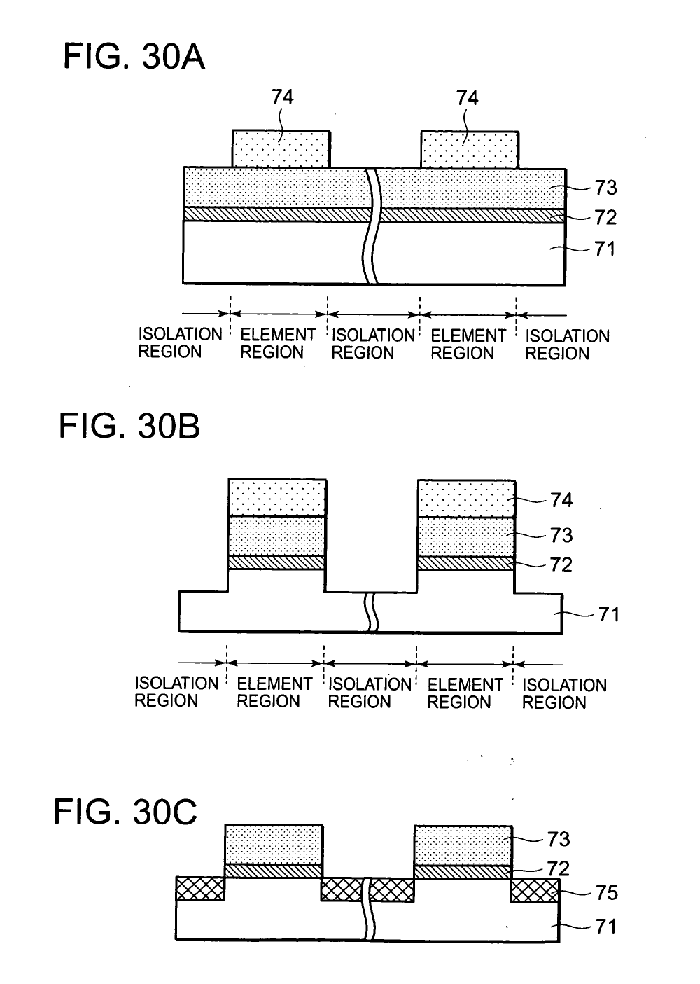

FIG. 30 to FIG. 33 are cross-sectional drawings illustrating a method for manufacturing a MOS transistor which has a silicide structure related to the third embodiment. The same codes are attached to parts which have structures similar to those in JP-A-1998-50636.

First, a silicon oxide film 72 and a silicon nitride film 73 are formed over a silicon substrate 71 as shown in FIG. 30A. Since the silicon nitride film 73 is used as a mask during selective implantation of arsenic in the following processes, the film thickness of the silicon nitride film 73 needs to be greater than the mean projected range of arsenic. Moreover, a resist 74 is coated over the silicon nitride film 73 and the resist 74 is patterned by a lithography technique to make a hole opening over the isolation region.

Next, as shown in FIG. 30B, the surfaces of the silicon nitride film 73, the silicon oxide film 72, and the silicon substrate 71 are, etched, in order, by using a dry etching technique. At this time, the region of the silicon substrate 71 underneath the rest of the silicon nitride film 73 becomes a transistor active region (element region) and the region of the silicon substrate 71 where the surface is etched to be hollow becomes an isolation region.

Next, as shown in FIG. 30C, the heat treatment is performed in a H₂O₂ atmosphere after removing the resist 74; the silicon substrate 71 is oxidized to form a field oxide film 75 which is an isolation insulating film in the isolation region.

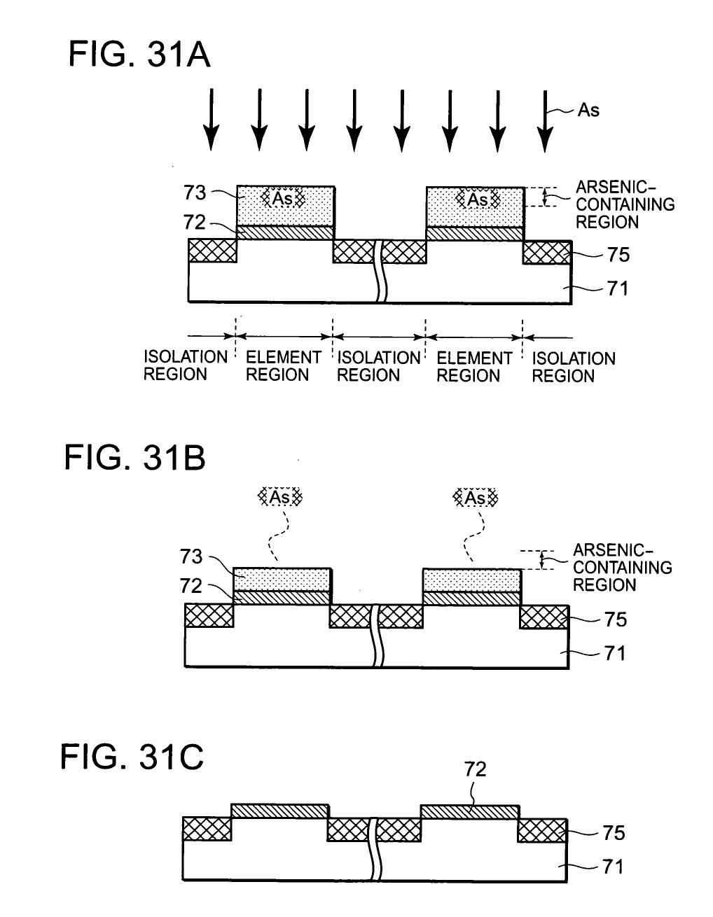

Next, as shown in FIG. 31A, selective implantation of arsenic ions is performed on the entire surface of the wafer under the conditions of an implantation energy of 10 keV and a dosage of 3×10¹⁵ cm⁻². According to this ion implantation, arsenic is injected into the field oxide film 75. Arsenic injected in the field oxide film 73 effectively acts to suppress the silicidation over the field oxide film 75. According to this ion implantation, arsenic is injected into the silicon nitride film 73 which was, used as a mask down to a predetermined depth, resulting in a region where arsenic is included in the silicon nitride film 73 (arsenic including region) being formed.

Next, as shown in FIG. 31B, the silicon nitride film 73 is etched by dry etching until the depth where arsenic is injected. Specifically, for the purpose of removal of arsenic included in the FG silicon nitride film 73, etching is performed on the arsenic including region in the silicon nitride film 73 (first etching process). Dry etching is performed using gases in a fluorine system gaseous atmosphere, for instance, 70 sccm of NF₃, 1800 sccm of O₂, 500 sccm of N₂ and under a pressure of 25 Pa. The detection of the end point of dry etching is done in the same way as the first embodiment.

Moreover, in this dry etching process, the exposed field oxide film 75 is damaged by the plasma. In other words, the field oxide film 75 is scraped by dry etching. However, since implantation of arsenic into the silicon nitride film 73 is performed only on the shallow region of the upper part, the time required for dry etching (etching time) can be made shorter. As a result, the amount that the field oxide film 75 is etched can also be suppressed to be small. Moreover, the amount that the field oxide film 75 is etched is sufficiently smaller than the total thickness of the field oxide film 75, so that there are almost no adverse effects (deterioration of the electrical insulating property, etc.) from which the field oxide film 75 suffers due to this dry etching.

Next, as shown in FIG. 31C, etching is performed on the rest of the silicon nitride film 73 by wet etching using phosphoric acid (second etching process). Wet etching is performed by dipping it, for instance, in a H₃PO₄ solution with a concentration of 86% which has been heated up to 160° C. for a predetermined time. As a result, the silicon nitride film 73 which has become unnecessary is completely removed. If all of the arsenic included in the silicon nitride film 73 is completely removed in the first etching process, the reaction product (particles) including arsenic is never produced in the wet etching liquid in the second etching process and contamination of the wet etching liquid hardly occurs.

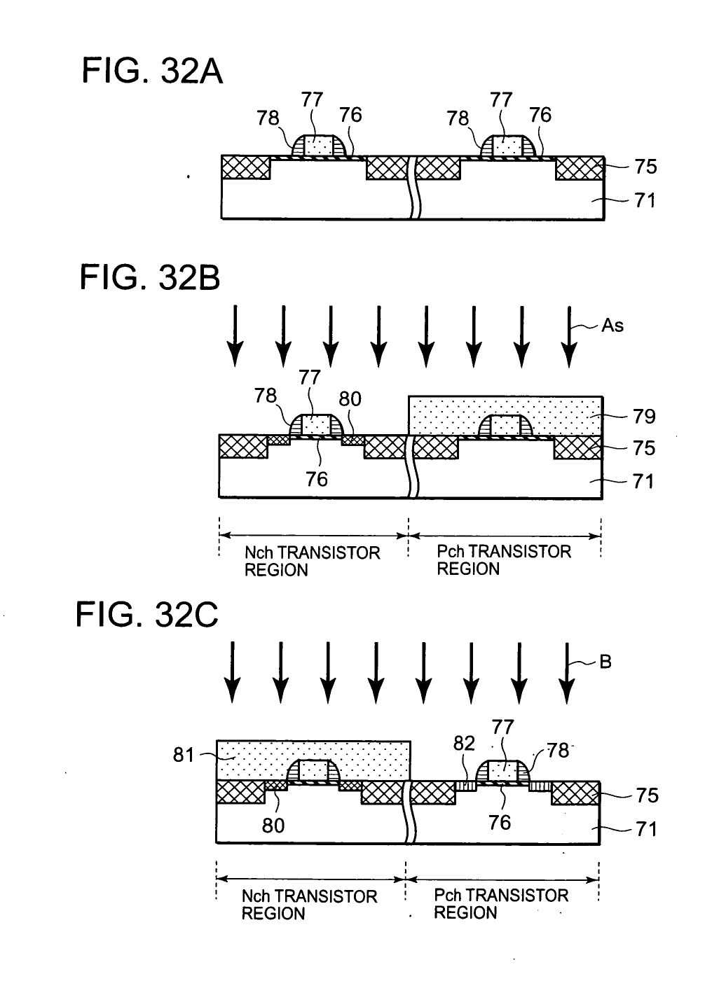

Next, as shown in FIG. 32A, the silicon oxide film 72 is removed by using a wet etching technique, and the gate oxide film 76 is formed continuously using a thermal oxidation technique. Then, a polysilicon gate electrode 77 is formed over the gate oxide film 76. After forming the polysilicon gate electrode 77, the silicon nitride film is formed and a sidewall spacer 78 is formed by anisotropic dry etching.

Next, as shown in FIG. 32B, selective implantation of arsenic ions is performed on the region where a Pch transistor is formed under a condition where it is covered with the resist pattern 79. According to the subsequent activation heat treatment, an N⁺ diffusion layer 80 which will be a source/drain of an Nch transistor is formed over the silicon substrate 71.

Next, as shown in FIG. 32C, after removing the resist pattern 79, selective implantation of boron ions is performed under a condition that the region where the Nch transistor (Nch transistor region) being formed is covered with the resist pattern 81. According to the subsequent heat treatment, a P⁺ diffusion layer 82 which will be a source and drain of the Pch transistor is formed over the silicon substrate 71.

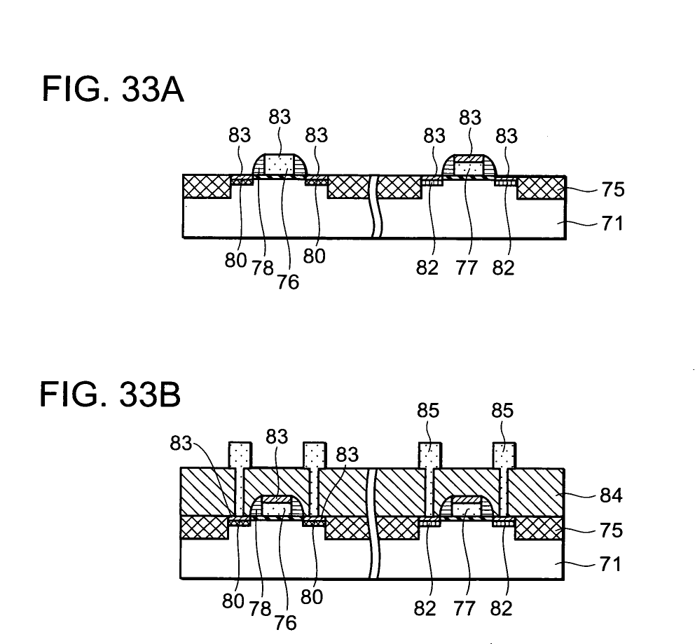

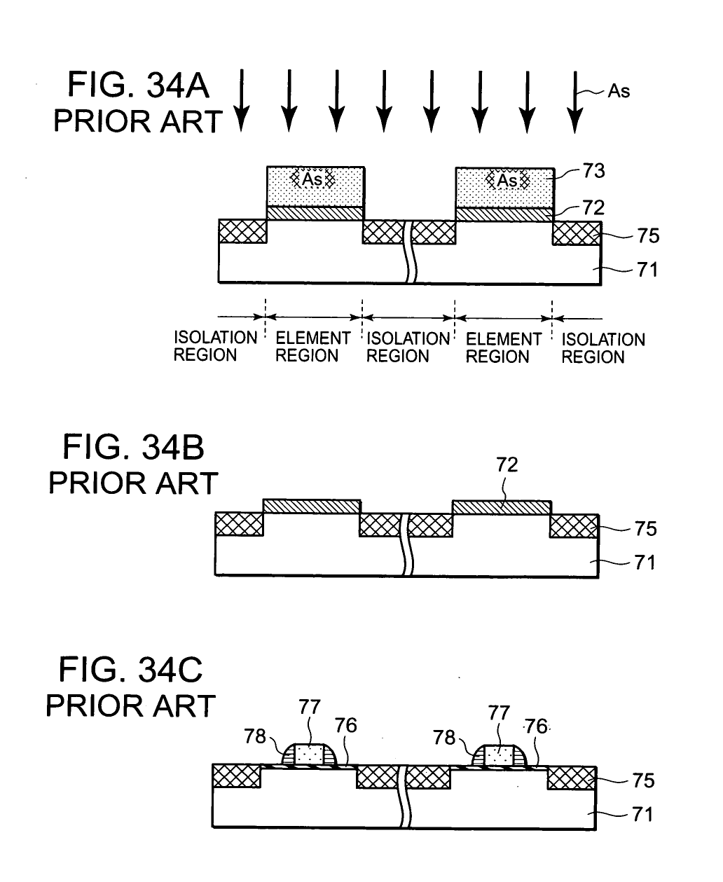

Next, a titanium film is deposited over the entire surface thereof by a sputtering technique using a metal; titanium silicidation occurs by heat treatment in a nitrogen atmosphere; resulting in a C49 structure titanium silicide layer which is a crystal structure having high electrical resistivity and in a titanium nitride being formed over the exposed surface of the polysilicon gate electrode 77 and the surfaces of the N⁺ diffusion layer 80 and P⁺ diffusion layer 82. At this time, at the region into which boron is injected, boron included in the field oxide film 75 disturbs the silicidation and prevents the formation of a short path crossing the diffusion layers. After that, the titanium nitride is removed and, as shown in FIG. 33A, the exposed surface of the polysilicon gate electrode 77, the C49 structure titanium silicide layer over the surface of the N⁺ diffusion layer 80 and the P⁺ diffusion layer 82 is changed into a C54 structure titanium silicide layer 83 which has low electrical resistivity.

Then, an interpoly dielectric layer 84 and an aluminum interconnect 85 are formed. Thus, a MOS transistor having a silicide structure is formed.

As described above, similar to the first embodiment and second embodiment of the present invention, the silicon nitride film 73 used as a mask during selective implantation of arsenic which is an N-type impurity is etched in the two-step process of the dry etching (first etching process) and the wet etching (second etching process) in the third embodiment of the present invention. In the first etching process which is performed first, etching is performed on the region which includes arsenic in the silicon nitride film 73. Moreover, in the following second etching process, the rest of the silicon nitride film 73 is removed without plasma damage. If all of the arsenic included in the silicon nitride film 73 could be removed by the first etching process, the reaction product (particles) including arsenic is never produced in the wet etching liquid during the second etching process. Specifically, it becomes possible to suppress the in-process discrepancies which may occur in the following manufacturing process, and reuse of the wet etching liquid becomes possible.

Similar to the first embodiment and the second embodiment, the first etching process is not limited to remove all the arsenic included in the silicon nitride film 73 even in the third embodiment.

As mentioned above, the preferred embodiments are explained, but there is a case where the reaction product may adhere to the semiconductor device without being completely exhausted from the etching chamber after the first process. In such a case, the semiconductor device may be washed by an acid prior to the second etching process.

Although the invention has been described above in connection with several preferred embodiments thereof, it will be appreciated by those skilled in the art that those embodiments are provided solely for illustrating the invention, and should not be relied upon to construe the appended claims in a limiting sense.

What is claimed is:

1. A method for manufacturing a semiconductor device comprising:
forming a silicon nitride film having a first part where arsenic is included and a second part where less amount of or substantially no arsenic is included;
removing at least a portion of the first part by dry etching;
removing at least a portion of the second part by wet etching.

2. The method for manufacturing the semiconductor device according to claim 1, wherein
the step of forming the silicon nitride film includes:
covering a substrate with the silicon nitride film having an opening; and
injecting arsenic by using the silicon nitride film as a mask.

3. The method for manufacturing the semiconductor device according to claim 2, wherein
the step of forming the silicon nitride film further includes:
forming a diffusion region on the substrate by injecting arsenic.

4. The method for manufacturing the semiconductor device according to claim 2, further comprising:
heat treating the substrate after the step of removing at least the portion of the second part.

5. The method for manufacturing the semiconductor device according to claim 2,
wherein an insulating film is selectively formed on the substrate, and
the opening is formed at a position corresponding to the insulating film.

6. The method for manufacturing the semiconductor device according to claim 1,
wherein the dry etching is performed by using a fluorine system etching gas, and
the wet etching is performed by using a phosphoric acid solution.

7. A method for manufacturing a semiconductor device comprising:
forming a conductive layer for a floating gate over a semiconductor layer intervening a gate insulating film therebetween;
removing the conductive layer selectively using a silicon nitride film having an opening as a mask;
providing a first injection of arsenic using the silicon nitride film as a mask to form a first diffusion layer on the semiconductor layer located at a position corresponding to the opening;
removing at least a part of a region where arsenic is included in the silicon nitride film by dry etching; and
removing at least a part of a rest of the silicon nitride film by wet etching.

8. The method for manufacturing the semiconductor device according to claim 7, further comprising:
forming a spacer over a sidewall of the silicon nitride film in the opening; and
selectively removing the conductive layer which is exposed by the wet etching by using the spacer as a mask.

9. The method for manufacturing the semiconductor device according to claim 8, further comprising:
forming a control gate insulated from the conductive layer intervening a tunneling insulating film.

10. The method for manufacturing the semiconductor device according to claim 9, further comprising:
injecting an impurity using the control gate as a mask to form a second diffusion layer on the semiconductor layer.

11. The method for manufacturing the semiconductor device according to claim 7, further comprising:
forming a plug over the first diffusion layer; and
providing a second injection of arsenic into an upper part of the plug using the silicon nitride film as a mask.

12. A method for manufacturing a semiconductor device comprising:
covering a semiconductor substrate in an element region with a silicon nitride film;
covering the semiconductor substrate in a different region from the element region with an isolation insulating film;
injecting arsenic into the isolation insulating film using the silicon nitride film as a mask;
removing at least a part of a region where arsenic is included in the silicon nitride film by dry etching;
removing at least a part of a rest of the silicon nitride film by wet etching;
forming a gate electrode over the semiconductor substrate intervening the gate insulating film therebetween in the element region;
forming an impurity diffusion region which will be a source and drain on the semiconductor substrate in the element region;
forming a metallic film over the entire surface; and
performing a heat treatment to form a silicide layer by reacting the surface of the impurity diffusion region with the metallic film.
